(19) United States
(12) Patent Application Publication
(10) Pub. No.: US 2022/0005743 A1
(43) Pub. Date: Jan. 6, 2022

(54) SEMICONDUCTOR MODULE AND SEMICONDUCTOR DEVICE USED THEREFOR

(71) Applicant: DENSO CORPORATION, Kariya-city (JP)

(72) Inventors: Seigo OSAWA, Kariya-city (JP); Yasushi OKURA, Kariya-city (JP); Takahiro NAKANO, Kariya-city (JP); Naohito MIZUNO, Kariya-city (JP); Masayuki TAKENAKA, Kariya-city (JP); Yoshihiro INUTSUKA, Kariya-city (JP)

(21) Appl. No.: 17/476,326

(22) Filed: Sep. 15, 2021

Related U.S. Application Data
(63) Continuation of application No. PCT/JP2020/010845, filed on Mar. 12, 2020.

(30) Foreign Application Priority Data
Mar. 19, 2019 (JP) 2019-051516
Feb. 20, 2020 (JP) 2020-027188

(51) Int. Cl. H01L 23/367; H01L 23/31; H01L 23/495

(52) U.S. Cl. CPC H01L 23/367; H01L 23/49541; H01L 23/3107

(57) ABSTRACT

A semiconductor module includes a first heat sink member, a semiconductor device, a second heat sink member, a lead frame, a second sealing member. The semiconductor device includes a semiconductor element, a first sealing member for covering the semiconductor element, a first wiring and a second wiring electrically connected to the semiconductor element, and a rewiring layer on the semiconductor element and the sealing member. The second heat sink member is disposed on the semiconductor device. The lead frame is electrically connected to the semiconductor device through a bonding member. The second sealing member covers a portion of the first heat sink member, the semiconductor and a portion of the second heat sink member. A surface of the second heat sink member faces the semiconductor device. The semiconductor device has a portion protruded from an outline of the second surface sink member.

### CROSS REFERENCE TO RELATED APPLICATIONS

The present application is a continuation application of International Patent Application No. PCT/JP2020/010845 filed on Mar. 12, 2020, which designated the U.S. and claims the benefit of priority from Japanese Patent Application No. 2019-051516 filed on Mar. 19, 2019 and Japanese Patent Application No. 2020-027188 filed on Feb. 20, 2020. The entire disclosures of all of the above applications are incorporated herein by reference.

### TECHNICAL FIELD

The present disclosure relates to a semiconductor module and a semiconductor device used for the semiconductor module.

### BACKGROUND

A semiconductor module may have a double-sided heat sink structure. The semiconductor module may include a power semiconductor device such as an insulated gate bipolar transistor (IGBT) and two heat sink members. The two heat sink members may be disposed to be opposite to each other and the power semiconductor may be sandwiched between the two heat sink members.

### SUMMARY

The present disclosure describes a semiconductor device provided for a semiconductor module including a first heat sink member, a second heat sink member, a lead frame and a sealing member.

### BRIEF DESCRIPTION OF DRAWINGS

Objects, features and advantages of the present disclosure will become more apparent from the following detailed description made with reference to the accompanying drawings. In the drawings:

FIG. 1 is a plan view showing a semiconductor module according to a first embodiment;

FIG. 2 is a cross-sectional view illustrating a semiconductor device in FIG. 1;

FIG. 3 is a perspective view showing the semiconductor device in FIG. 2;

FIG. 4 is a plan view showing a semiconductor module in a comparative example;

FIG. 5A is a cross-sectional view illustrating a process for preparing a semiconductor substrate as a manufacturing process of the semiconductor device in a manufacturing process of the semiconductor module in FIG. 1;

FIG. 5B is a cross-sectional view illustrating a manufacturing process of the semiconductor device subsequent to FIG. 5A;

FIG. 5C is a cross-sectional view illustrating a manufacturing process of the semiconductor device subsequent to FIG. 5B;

FIG. 5D is a cross-sectional view illustrating a manufacturing process of the semiconductor device subsequent to FIG. 5C;

FIG. 5E is a cross-sectional view illustrating a manufacturing process of the semiconductor device subsequent to FIG. 5D;

FIG. 5F is a cross-sectional view illustrating a manufacturing process of the semiconductor device subsequent to FIG. 5E;

FIG. 5G is a cross-sectional view illustrating a manufacturing process of the semiconductor device subsequent to FIG. 5F;

FIG. 5H is a cross-sectional view illustrating a manufacturing process of the semiconductor device subsequent to FIG. 5G;

FIG. 5I is a cross-sectional view illustrating a manufacturing process of the semiconductor device subsequent to FIG. 5H,

FIG. 5J is a cross-sectional view illustrating a manufacturing process of the semiconductor device subsequent to FIG. 5I;

FIG. 5K is a cross-sectional view illustrating a manufacturing process of the semiconductor device subsequent to FIG. 5J;

FIG. 5L is a cross-sectional view illustrating a manufacturing process of the semiconductor device subsequent to FIG. 5K;

FIG. 5M is a cross-sectional view illustrating a manufacturing process of the semiconductor device subsequent to FIG. 5L;

FIG. 6A is a cross-sectional view illustrating a process for mounting a semiconductor device as a manufacturing process of the semiconductor module in FIG. 1;

FIG. 6B is a cross-sectional view illustrating a manufacturing process of the semiconductor device subsequent to FIG. 6A;

FIG. 6C is a diagram showing a manufacturing process following FIG. 6B;

FIG. 6D is a cross-sectional view illustrating a manufacturing process of the semiconductor device subsequent to FIG. 6B;

FIG. 7 is a plan view showing a semiconductor module according to a second embodiment;

FIG. 8 is a plan view showing a semiconductor module according to a third embodiment;

FIG. 9 is a perspective view showing the semiconductor device in the semiconductor module in FIG. 8;

FIG. 10 is a plan view showing an example of the arrangement of configuration elements in the semiconductor module in FIG. 8;

FIG. 11 is a cross-sectional view showing a semiconductor module according to the modification of the third embodiment;

FIG. 12 is a cross-sectional view showing an example of the structure of a lead frame in a semiconductor module according to a fourth embodiment;

FIG. 13 is a view in the direction of arrow XIII in FIG. 12;

FIG. 14 illustrates a stress generated at the lead frame without a stress relaxing portion;

FIG. 15 illustrates the first modification of the stress relaxing portion, and is an arrow view corresponding to FIG. 13;

FIG. 16 illustrates the second modification of the stress relaxing portion, and is an arrow view corresponding to FIG. 13;

FIG. 17 is a view in the direction of arrow XVII in FIG. 16;

FIG. 18 is a cross-sectional view of the structure of a semiconductor module according to a fifth embodiment;

FIG. 19 is a diagram for explaining a surface of a heat sink facing the semiconductor device;

FIG. 20 illustrates the gap formed between the other surface of the heat sink and a surface of the semiconductor device;

FIG. 21 is a cross-sectional view showing a semiconductor module according to the modification of the fifth embodiment;

FIG. 22 is a cross-sectional view showing an example of the structure of a semiconductor device in a semiconductor module according to a sixth embodiment;

FIG. 23 is a cross-sectional view showing an example of the structure of a lead frame in a semiconductor module according to a seventh embodiment;

FIG. 24 is a cross-sectional view of the structure of a lead frame according to in the modification of the seventh embodiment;

FIG. 25 is a cross-sectional view showing an example of the structure of a semiconductor device in a semiconductor module according to an eighth embodiment;

FIG. 26 is a plan view of the arrangement of protrusions of the semiconductor device according to the eighth embodiment as an example of the arrangement;

FIG. 27 is a plan view of the arrangement of protrusions of the semiconductor device according to the eighth embodiment as another example of the arrangement;

FIG. 28 is a cross-sectional view of the structure in the other modification of the third embodiment;

FIG. 29 is a cross-sectional view of the structure of a semiconductor device in the modification of the other embodiment;

FIG. 30 is a cross-sectional view of the structure in the modification of the second embodiment;

FIG. 31 is a cross-sectional view of the structure in the other modification of the third embodiment;

FIG. 32 is a cross-sectional view of the structure in the modification of the first embodiment;

FIG. 33 illustrates a molding process of a sealing member in the manufacturing process of the semiconductor module in FIG. 32;

FIG. 34 is a cross-sectional view of the structure in the other modification of the fifth embodiment; and

FIG. 35 is a cross-sectional view of the structure of the semiconductor module with a thermal conduction insulating substrate having a stepped portion.

### DETAILED DESCRIPTION

In a semiconductor module, a lower heat sink, a power semiconductor device, a heat sink block, an upper heat sink may be stacked in this order through a solder. The semiconductor module may have a lead frame, a wire and a sealing member. The wire may electrically connect the lead frame and the gate of the power semiconductor device. A sealing member may cover the lead frame and the wire. In the semiconductor module, the surface of the lower heat sink and the surface of the upper heat sink opposite to the power semiconductor element may be exposed from the sealing member. In other words, the semiconductor module may dissipate heat generated through the electrical conduction to the power semiconductor device through two heat sinks, in other words, heat sink members.

In the semiconductor module described above, a heat sink block may be disposed so that the gap between the two heat sink members is set to a predetermined value or larger, and the heat sink member and the wire are prevented from coming into contact with each other and having a short-circuit. However, the heat sink block may hinder the thinning or miniaturization of the semiconductor module, and may enlarge the thermal resistance from the power semiconductor device to the heat sink member.

According to a first aspect of the present disclosure, a semiconductor module includes a first heat sink member, a semiconductor device, a second heat sink member, a lead frame, a second sealing member. The semiconductor device includes a semiconductor element, a first sealing member for covering the semiconductor element, a first wiring and a second wiring electrically connected to the semiconductor element, and a rewiring layer disposed on the semiconductor element and the sealing member. The second heat sink member is disposed on the semiconductor device. The lead frame is electrically connected to the semiconductor device through a bonding member. The second sealing member covers a portion of the first heat sink member, the semiconductor and a portion of the second heat sink member. The second heat sink member has a first surface and a second surface. The second surface of the second heat sink member faces the semiconductor device. The semiconductor device has a portion protruded from an outline of the second surface of the second heat sink member. The second wiring has one end extending to the portion of the semiconductor device protruded from the outline of the second surface of the second heat sink member, and the one end of the second wiring is electrically connected to the lead frame through the bonding member.

According to the first aspect of the disclosure, in the semiconductor module having a double-sided heat sink structure, the semiconductor device and the second heat sink member are connected through the bonding member, and the lead frame and the semiconductor device are connected through the bonding member. Therefore, the semiconductor module does not require a heat sink block and a wire, which are needed in a comparative structure. Thus, the thickness and thermal resistance in the semiconductor module may be decreased due to eliminating the parts such as the heat sink block and the wire. The semiconductor module according to the above aspect of the present disclosure has advantageous effects in miniaturizing the structure and lowering the thermal resistance.

According a second aspect of the present disclosure, a semiconductor device includes a semiconductor element, a sealing member and a rewiring layer. The sealing member surrounds the semiconductor element. The rewiring layer is disposed on the semiconductor and the sealing member. The semiconductor device is provided for a semiconductor module having a double-sided heat sink structure with a first heat sink member and a second heat sink member. The semiconductor device is disposed between the first heat sink member and the second heat sink member. The rewiring layer includes an insulating layer, a first wiring layer and a second wiring layer. An end of the first wiring is connected to the semiconductor element. A first end of the second wiring is connected to the semiconductor element. The first wiring is disposed inside an outline of the semiconductor element in a top view of the semiconductor device. A second end of the second wiring extends outwards from the outline of the semiconductor element in the top view of the semiconductor device.

According to the second aspect of the present disclosure, it is possible to bond the second heat sink member and the lead frame through the solder without adopting the heat sink block and the wire in the semiconductor device. The semiconductor device according to the above aspect may be applied for manufacturing the semiconductor module having the advantageous effects in miniaturizing the structure and lowering the thermal resistance as compared with comparative structures.

The following describes multiple embodiments with reference to the drawings. Hereinafter, in the respective embodiments, substantially the same configurations are denoted by identical symbols, and repetitive description will be omitted.

### First Embodiment

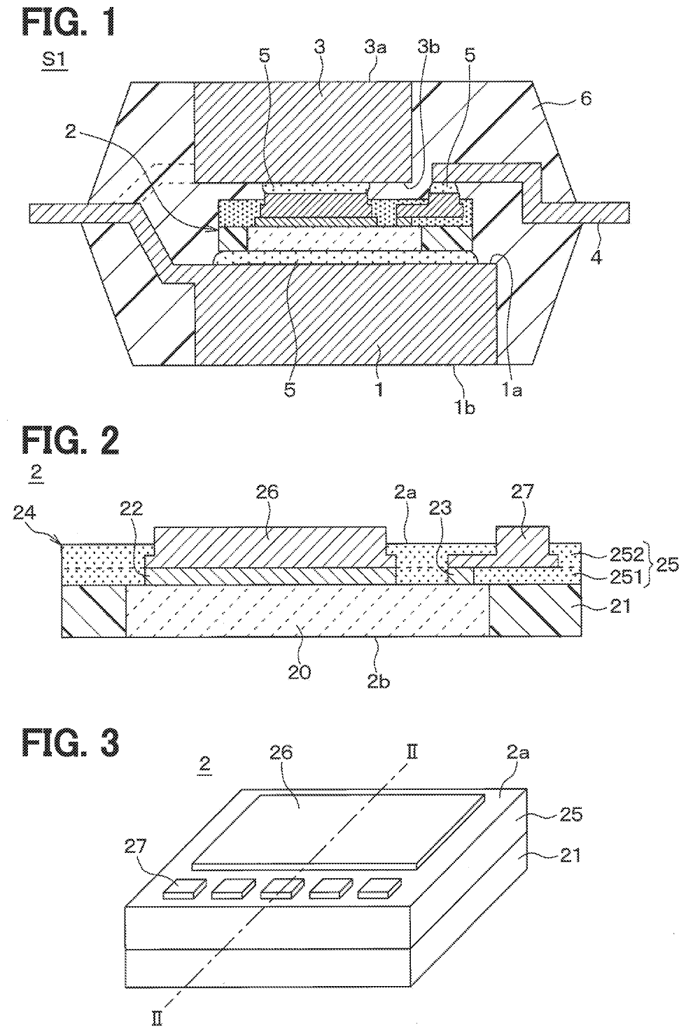

The following describes a semiconductor module S1 according to the first embodiment with reference to FIGS. 1 to 3. The semiconductor module S1 may be applied for use in, for example, a power conversion device that converts a direct current into an alternating current to supply power to a travelling motor of an automobile. The semiconductor module S1 may also be referred to as a “power card”.

FIG. 1 illustrates a wiring portion connected to outside in another cross sectional view of a second heat sink 3 described hereinafter with a broken line. FIG. 2 illustrates the boundary of a region where an insulating layer 25 described hereinafter is partitioned. FIG. 2 corresponds to a cross sectional view between line II-II indicated as a one-dotted chain line in FIG. 3.

(Structure)

The semiconductor module S1 according to the present embodiment includes a first heat sink 1, a semiconductor device 2, the second heat sink 3, a lead frame 4, a bonding member 5 and a sealing member 6, as illustrated in FIG. 1. The semiconductor module S1 includes two heat sinks 1, 3 disposed to face each other with the semiconductor device 2 interposed between two heat sinks 1, 3. The semiconductor module S1 is a double-sided heat sink structure in which heat generated by the semiconductor device 2 is dissipated outwards from both surfaces of the semiconductor device 2 through the heat sinks 1, 3. The sealing member 6 may also be referred to as a second sealing member.

As illustrated in FIG. 1, the first heat sink 1 has a plate shape having an upper surface 1a and a lower surface 1b, and is made of, for example, a metal material such as copper or iron. The upper surface 1a may be referred to as a main surface, and a low surface 1b may be referred to as a rear surface. The semiconductor device 2 is mounted on the upper surface 1a of the first heat sink 1 via the bonding member 5 made of a solder, and the lower surface 1b of the first heat sink 1 is exposed from the sealing member 6. In the present embodiment, the first heat sink 1 is adopted as a current path for the electrical conduction of the semiconductor device 2, and a part of the heat sink 1 near the upper surface 1a is extended to an exterior part of the sealing member 6. In other words, the first heat sink 1 acts as a heat sink member and wiring in the present embodiment. The first heat sink 1 may also be referred to as a “first heat sink member”.

As illustrated in FIG. 2, the semiconductor device 2 has a plate shape having a main surface 2a and a rear surface 2b. The semiconductor device 2 includes a semiconductor element 20, a sealing member 21, a first electrode 22, a second electrode 23 and a rewiring layer 24. The semiconductor device 2 is a fan-out package structure (hereinafter simply referred to as an “FO package structure”). The semiconductor device 2 includes a second wiring 27 connected to the second electrode 23 as a portion of the rewiring layer 24, and one end of the second wiring 27 is extended to the outside of the outline of the semiconductor element 20. The semiconductor device 2 may have an FO package structure, or may have a wafer level package structure, or may have a panel level package structure. The sealing member 21 may also be referred to as a first sealing member.

As illustrated in FIG. 1, the semiconductor device 2 is arranged inside the outline of the upper surface 1a of the first heat sink 1. The semiconductor device 2 has a structure in which a part of the second heat sink 3 protrudes outward from the outline of the other surface 3b facing the second heat sink 3, and one end of the second wiring 27 extends to the protruding portion. Since the wiring connection with the lead frame 4 and the heat sink block between the semiconductor device 2 and the second heat sink 3 are not required, it is possible to lower the thermal resistance and make the semiconductor module thinner. The details of this structure is described hereinafter.

The semiconductor element 20 is made of semiconductor material such as silicon or silicon carbide, and is a power semiconductor device such as a metal-oxide-semiconductor field-effect transistor (MOSFET) or an insulated gate bipolar transistor (IGBT). The semiconductor element 20 is manufactured by semiconductor processes. In the semiconductor element 20, a third electrode (not shown) is formed on a surface opposite to the surface where the first electrode 22 and the second electrode 23 are formed, and the third electrode is electrically connected to the upper surface 1a of the first heat sink 1 through the bonding member 5.

As illustrated in FIG. 2, the sealing member 21 is a member covering the surrounding of the semiconductor element 20, and is made of an arbitrary resin material such as an epoxy resin. The sealing member 21 covers the end surface of the semiconductor element 20, and is included in the rear surface 2b of the semiconductor device 2 and a surface opposite to the surface where the first electrode 22 of the semiconductor element 20 is formed.

The first electrode 22, the second electrode 23 and the third electrode (not shown) are made of, for example, a metal material such as copper, and are formed on one surface of the semiconductor element 20 through, for example, electrolytic plating. The first electrode 22 and the third electrode are formed as a pair of electrodes, and the pair serves as a main current path of the semiconductor element 20. The first electrode 22 is, for example, an emitter electrode. Multiple second electrodes 23 are provided, and at least one of them is, for example, a gate electrode, and is adopted for allowing or blocking the current flowing between the first electrode 22 and the third electrode. The electrodes different from the gate electrode among the multiple second electrodes 23 are also adopted, for example, as sensor terminals on the element.

The first electrode 22, the second electrode 23 are made of a metal material such as copper through electrolytic plating similar to the first wiring 26 and the second wiring 27 in the manufacturing method described hereinafter to enhance heat dissipation, as compared with the structure made of material such as aluminum.

As illustrated in FIG. 2, the rewiring layer 24 includes an insulating layer 25, a first wiring 26 connected to the first electrode 22, and a second wiring 27 connected to the second electrode 23, and is formed on the semiconductor element 20 and the sealing member 21 by rewiring techniques.

The insulating layer 25 is made of an insulating material such as polyimide, and is formed by, for example, an arbitrary coating process.

The first wiring 26 and the second wiring 27 are made of, for example, a metal material such as copper, and are formed by electrolytic plating. The first wiring 26 is formed inside the outline of the semiconductor element 20 in a top view, and one end of the first wiring 26 is thermally and electrically connected to the second heat sink 3 through the bonding member 5. The second wiring 27 has one end extended outwards from the outline of the semiconductor element 20, and is electrically connected to the lead frame 4 through the bonding member 5. As illustrated in FIG. 3, for example, multiple second wirings 27 are formed, and one end of each second wiring 27 is extended to outwards from the outline of the semiconductor element 20. FIG. 3 illustrates an example in which five second wirings 27 are formed and connected to respective second electrodes 23. However, the number of the second electrodes 23 and the number of the second wirings 27 are arbitrary.

As illustrated in FIG. 1, the second heat sink 3 has a plate shape having a first surface 3a and a second surface 3b, and is made of the material identical to the one for the first heat sink 1. The first surface 3a may also be referred to a main surface, and the second surface 3b may be referred to as a rear surface. In the present embodiment, the second heat sink 3 is disposed to face a part of the main surface 2a of the semiconductor device 2. In the present embodiment, the second heat sink 3 is electrically connected to the first wiring 26 through the bonding member 5 to form a current path of the semiconductor element 20 identical to the first heat sink 1, and a portion of the second heat sink 3 near the second surface 3b is extended to the outside of the sealing member 6. In other words, the second heat sink 3 acts as both of the heat sink member and the wiring. The second heat sink 3 may also be referred to as a “second heat sink member”.

The lead frame 4 is made of a metal material such as copper or iron, and is electrically connected to the second wiring 27 of the semiconductor device 2 through the bonding member 5 as illustrated in FIG. 1. The lead frame 4 includes, for example, multiple leads having the same number as the number of the second electrodes 23. These leads are connected to the adjacent lead by a tie bar (not shown) until the formation of the sealing member 6, and the tie bar is removed by, for example, press punching after the formation of the sealing member 6. The lead frame 4 is configured as a member identical to the second heat sink 3, and may be connected by the tie bar (not shown) until the formation of the sealing member 6. Even in this situation, the lead frame 4 is separated from the second heat sink 3 by removing the tie bar through, for example, press punching after the formation of the sealing member 6.

The bonding member 5 is a jointing material that joins the configuration elements of the semiconductor module S1, and is a conductive material such as a solder used for making an electrical connection. The bonding member 5 is not limited to the solder, but at least a material different from the wire is used.

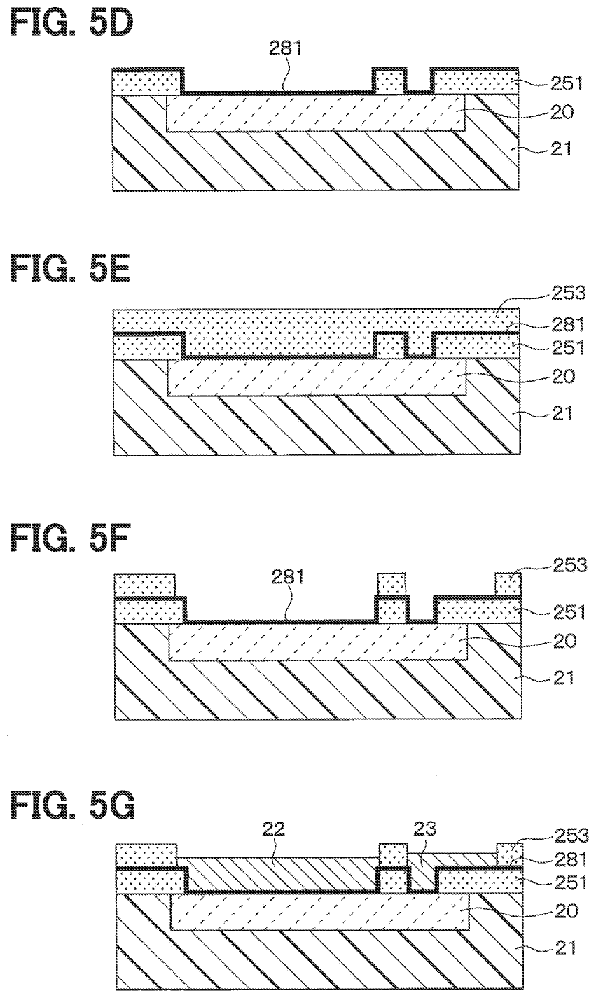

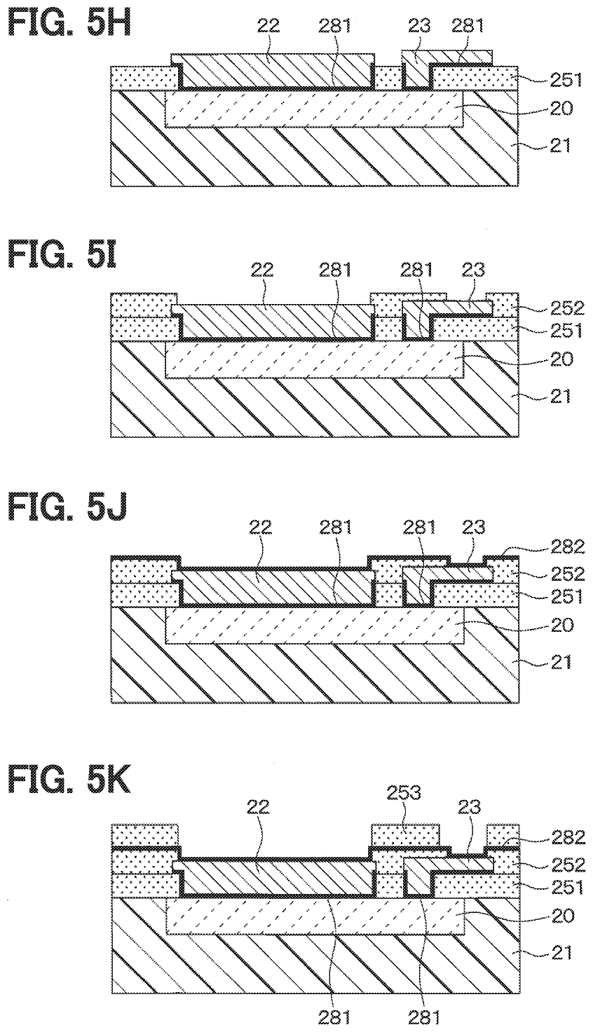

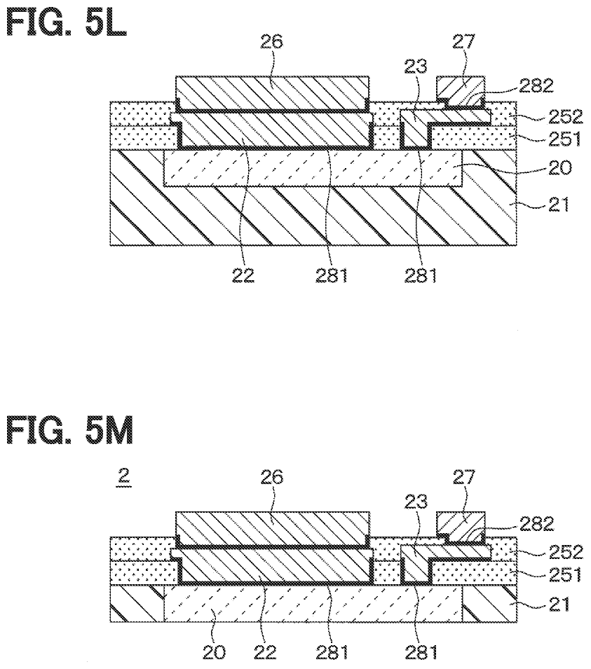

The sealing member 6 is made of, for example, a thermosetting resin such as an epoxy resin, and covers a portion of the heat sinks 1 and 3, the semiconductor device 2, a portion of the lead frame 4 and the bonding member 5 as illustrated in FIG. 5.

The above describes the structure of the semiconductor module S1 according to the present embodiment.

### Advantageous Effects

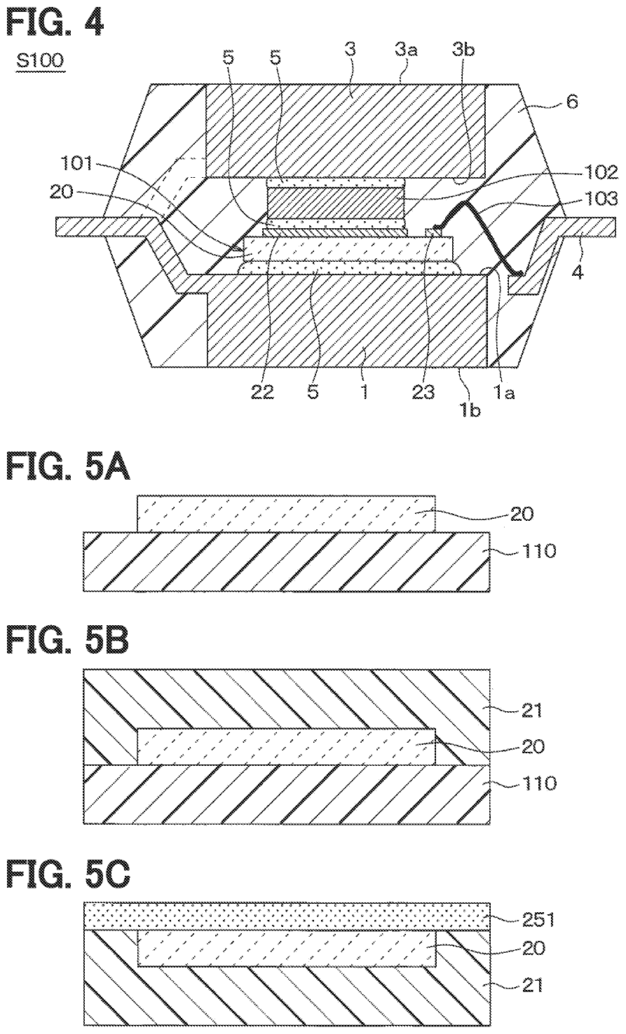

The following describes the advantageous effects generated in the semiconductor module S1 according to the present embodiment based on a comparison with a semiconductor module S100 having a comparative structure as illustrated in FIG. 4.

The following describes the semiconductor module S100 having a comparative structure. The following mainly describes the difference between the structure of the semiconductor module S100 and the structure of the semiconductor device 2.

As illustrated in FIG. 4, the semiconductor module S100 having a comparative structure includes a semiconductor device 101, heat sinks 1 and 3, a heat sink block 102, a wire 103, a lead frame 4, a bonding member 5 and a sealing member 6. The heat sinks 1 and 3 are disposed to face each other, and the semiconductor device 101 is sandwiched between the heat sinks 1 and 3.

As illustrated in FIG. 4, the semiconductor device 101 includes a semiconductor element 20 having a first electrode 22, a second electrode 23 and a third electrode (not shown), and is different from the semiconductor device 2. The semiconductor device 101 does not have the sealing member 21 and the rewiring layer 24. The semiconductor device 101 is mounted on the first heat sink 1 through the bonding member 5, and is disposed inside the outline of the upper surface 1a of the first heat sink 1 and inside the outline of the second surface 3b of the second heat sink 3.

The heat sink block 102 is made of the metal material such as copper, and one surface of the heat sink block 102 is connected to the first electrode 22 of the semiconductor element 20 through the bonding member 5 and the other one surface pf the heat sink block 102 is connected to the second heat sink 3 through the bonding member 5 as illustrated in FIG. 4. The heat sink block 102 is included in the current path of the semiconductor element 20, and conducts the heat generated by the semiconductor element 20 to the second heat sink 3. The heat sink block 102 sets the gap between the semiconductor element 20 and the second heat sink 3 to be a predetermined value or larger, and is disposed for preventing the wire 103 connected to the second electrode 23 be in contact with the second heat sink 3 and have a short-circuit.

The wire 103 is made of a metal material such as aluminum or gold, and is bonded to the second electrode 23 and the lead frame 4 by wire bonding, and is electrically connected to the second electrode 23 and the lead frame 4.

Since it is required for the semiconductor module S100 to ensure the gap for disposing the heat sink block 102 between the semiconductor device 101 and the second heat sink 3, it may be difficult to further make the semiconductor module S100 thinner. In the semiconductor module S100, as a double-layered jointing material and one heat sink block 102 are arranged between the semiconductor device 101 and the second heat sink 3, the thermal resistance is enlarged by both of the double layered jointing material and one heat sink block 102.

In contrast, in the semiconductor module S1 according to the present embodiment, the semiconductor device 2 includes the rewiring layer 24, and a portion of the semiconductor device 2 protrudes from the outline of the second surface 3b of the second heat sink 3. In the semiconductor module S1, the second wiring 27 is extended from the outline of the second surface 3b of the second heat sink 3 of the semiconductor device 2, and is bonded to the lead frame 4 through the bonding member 5 made of the solder. In the semiconductor module S1, it is possible to join the semiconductor device 2 and the second heat sink 3 directly by soldering, and the heat sink block 102 and the wire 203 are not needed.

As a result, only a single-layered bonding member 5 connects the semiconductor device 2 and the second heat sink 3. The thickness is reduced by the amount of the heat sink block 102 and the single-layer bonding member 5, and the thermal resistance is smaller. The semiconductor device 2 has the FO package structure to join the lead frame 3 through soldering, and is applicable to the thinning and lowering the thermal resistance of the semiconductor module having the double-sided heat sink structure. The semiconductor device 2 has the rewiring layer 24. Therefore, the planar size of the first electrode 22 and the second electrode 23, in other words, the planar size of the semiconductor element 20 can be made smaller so as to reduce the cost.

It is also considered that the area of the second heat sink 3 is simply reduced, and the second electrode 23 of the semiconductor element 20 without forming the rewiring layer 24 is disposed outside the outline of the second heat sunk 3 to connect the second electrode 23 and the lead frame 4 by the wire 103.

With regard to this method, although the heat sink block 102 is not needed and the thermal resistance becomes smaller due to the unnecessary heat sink block 102; however, the planer size of the second heat sink 3 also becomes smaller so that the thermal becomes larger due to the reduced planar size. As a result, the heat sink ability of the semiconductor module having such a structure may not change or may degrade as compared with a comparative module. In order to connect the wire 103, the planar size of the second electrode 23 must be enlarged, and the manufacturing cost is also increased due to the enlargement of the planar size of the semiconductor element 20. In a situation of adopting the wire 103, a wiring length is required for preventing the short-circuit, and the inductance becomes larger. Therefore, when the wire 103 is connected to an alternating current power supply, noise may be easily generated in a high-frequency signal.

Therefore, the semiconductor module S1 with the semiconductor device 2 having the FO package structure generates the advantageous effects in thinning of the structure and lowering the thermal resistance as compared with comparative structures. In addition, the manufacturing cost may be reduced due to miniaturization of the semiconductor element 20 and the noise may also be reduced in the high-frequency signal.

(Manufacturing Method)

The following describes an example of the method for manufacturing the semiconductor module S1 according to the present embodiment.

As illustrated in FIG. 5A, the semiconductor element manufactured by a semiconductor process is prepared, and a surface of the semiconductor element 20 for forming the first electrode 22 and the second electrode 23 is attached to a support substrate 110 and held. As the support substrate 110, for example, any one having an adhesive sheet (not shown) having high adhesion to silicon may be adopted.

A mold (not shown) is prepared, the semiconductor element 20 held on the support substrate 110 is covered with a resin material such as epoxy resin by compression molding or the like, and is hardened by heating or the like, as shown in FIG. 5B, to form the sealing member 21. The semiconductor element 20 covered by the sealing member 21 is peeled off from the support substrate 110.

A solution containing a photosensitive resin material such as polyimide is coated on the surface where the semiconductor element 20 is exposed and then is dried, a first layer 251 included in the insulating layer 25 is formed as illustrated in FIG. 5C.

As illustrated in FIG. 5D, a first seed layer 281 made of, for example, copper is formed by a vacuum forming method such as sputtering after patterning the first layer 251 by a photolithography etching method.

As illustrated in FIG. 5E, a resist layer 253 for covering the first layer 251 and the first seed layer 281 is formed. The resist layer 253 can be formed by, for example, a spin coating method similar to the first layer 251 by adopting the sensitive resin material.

The patterning of the resist layer 253 is performed by the process identical to the one for patterning the first layer 251, and an opening including a region removed by the first layer 251 is formed as illustrated in FIG. 5F.

A plating layer made of, for example, copper is formed by electrolytic plating or the like is formed, and the first electrode 22 and the second electrode 23 are formed as illustrated in FIG. 5G. Subsequently, a portion of the first wiring 26 and a portion of the second wiring 27 are formed.

As illustrated in FIG. 5H, after removing the resist layer 253 with, for example, a stripping solution, a portion of the first seed layer 281 exposed by the removal of the resist layer 253 is removed by the etching solution.

As illustrated in FIG. 5I, the second layer 252 included in the insulating layer 25 is formed by the spin coating method with the sensitive resin material similarly used for the first layer 251, and the patterning is performed by the photolithography etching method.

As illustrated in FIG. 5J, the second seed layer 282 made of, for example, copper is formed by the vacuum film forming method such as sputtering. After the formation of the second seed layer 282, the resist layer 253 is formed on the second layer 252 by the identical process as described above, and the patterning is performed. As illustrated in FIG. 5K, the resist layer 253 for covering the second layer 252, a portion of the first wiring 26 and a portion of the second wiring 27 is formed.

After the formation of the remaining part of the first wiring 26 and the second wiring 27 made of, for example, copper by the electroplating or the like, the resist layer 253 is removed by the stripping solution, and the second seed layer 282 exposed by the removal of the resist layer 253 is removed by, for example, the etching solution. As illustrated in FIG. 5L, the rewiring layer 24 including the first wiring 26 and the second wiring 27 is formed on the semiconductor element 20 and the sealing member 21.

As illustrated in FIG. 5M, a surface of the sealing member 21 opposite to the rewiring layer 24 is thinned by, for example, polishing to expose the semiconductor element 20. The third electrode (not shown) is formed on the exposed surface of the semiconductor element 20 by the vacuum forming method such as sputtering. The third electrode (not shown) may be formed at the exposed surface of the semiconductor element 20. The third electrode may also be formed at the entire surface of the polished surface containing the surface of the sealing member 21 opposite to the rewiring layer 24 in addition to the exposed surface. In the former case, it is possible to form the third electrode only at the exposed surface of the semiconductor element 20 by adopting a metal mask (not shown).

Although the above process can manufacture the semiconductor device 2, any one of other semiconductor processes may also be adopted. For example, in the process for preparing the semiconductor element 20 illustrated in FIG. 5A, it is also possible to prepare the semiconductor element 20 formed with the third electrode. In this situation, after covering the third electrode with the sealing member 21, the sealing member 21 is made to be thinner to expose the third electrode. As described above, the method for manufacturing the semiconductor device 2 may be modified as appropriate.

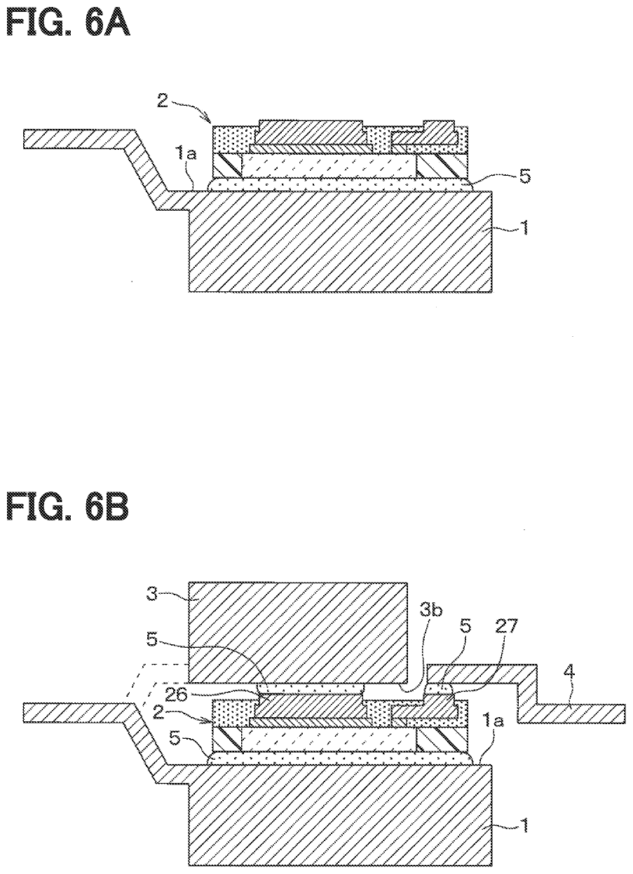

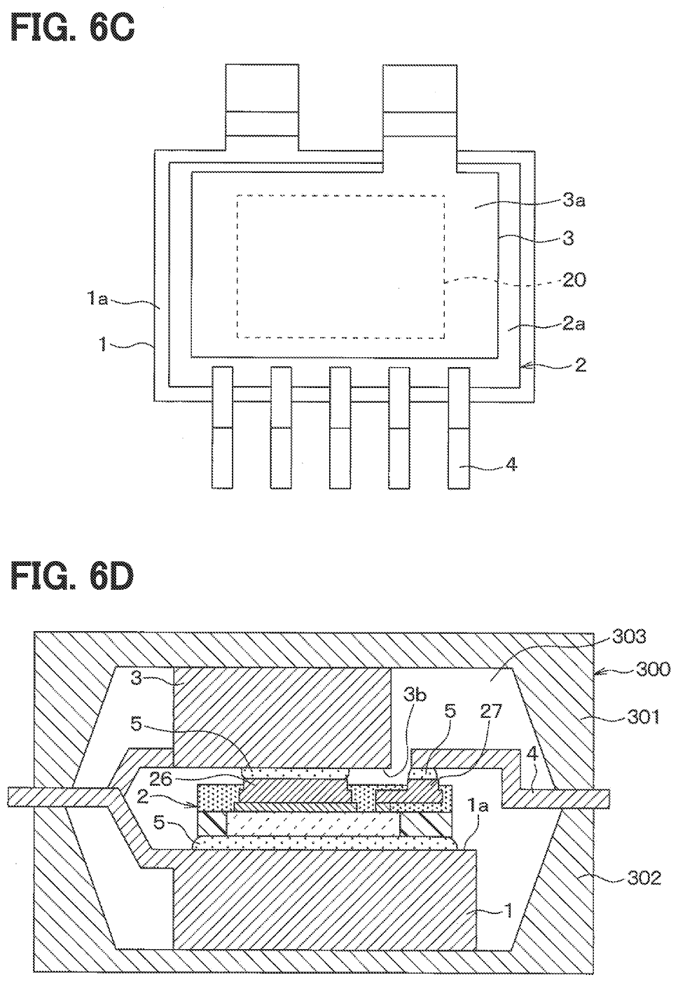

As illustrated in FIG. 6A, the first heat sink 1 made of a metal material such as copper is prepared, and the semiconductor device 2 is bonded onto the first heat sink 1 through soldering. The first heat sink 1 can be acquired by an arbitrary process such as the formation of a wiring portion connected to, for example, an external power supply through dry etching after press punching a metal plate made of copper.

As illustrated in FIG. 6B, after coating the solder on the first wiring 26 and the second wiring 27 of the semiconductor device 2, the second heat sink 3, which is separately prepared, is placed and bonded on the first wiring 26 through the solder, and the lead frame 4 is placed and bonded on the second wiring 27 through the solder. As illustrated in FIG. 6C, in a plan view, the semiconductor device 2 is disposed inside the outline of the first heat sink 1 and a portion of the semiconductor device 2 protrudes from the outline of the second heat sink 3, and the portion protruded from the outline of the second heat sink 3 is connected by the lead frame 4. As illustrated in FIG. 6C, the semiconductor device 2 may have a plane larger than a portion of at least one heat sink connected to the semiconductor device 2. In the molding of the sealing member 6 as described hereinafter, it is possible to fill the resin material and suppress the voids. The second heat sink 3 may be acquired by the process similar to the first heat sink 1. The lead frame 4 may be acquired by an arbitrary process such as press punching a metal plate made of copper. After the semiconductor device 2, the second heat sink 3 and the lead frame 4 is bonded through the solder, the semiconductor device 2 and the first heat sink 1 may be bonded through the solder.

As illustrated in FIG. 6D, a metallic mold 300 is prepared. The mold 300 includes an upper mold 301, a lower mold 302 and a cavity 303, which corresponds to the outer shape of the sealing member 6. The semiconductor device 2 bonded with the heat sinks 1, 3 and the lead frame 4 through the solder is put into the cavity 303. After this work is put in, a resin material such as epoxy resin is injected into the cavity 303 from an injection port (not shown), and the sealing member 6 is formed by hardening through, for example, heating. After forming the sealing member 6, the work is released from the metallic mold 300, and the tie bar of the lead frame 4 is removed by, for example, press punching. Thus, it is possible to manufacture the semiconductor module S1 according to the present embodiment.

According to the present embodiment, the semiconductor device 2 having the FO package structure is directly bonded to the second heat sink 3 and the lead frame 4 through the solder to form the semiconductor module S1 having a double-sided heat sink structure without having the heat sink block 102 and the wire 103. As compared with the comparative semiconductor module S100 having the heat sink block 102 and the wire 103, the semiconductor module S1 has advantageous effects in thinning the structure and lowering the thermal resistance.

### Second Embodiment

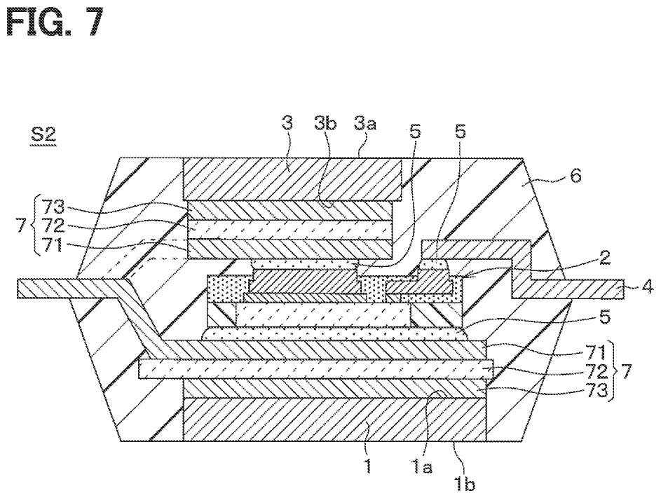

The following describes a semiconductor module S2 according to the first embodiment with reference to FIG. 7. FIG. 7 indicates a wiring extended outward from a heat-transfer insulated substrate 7 described hereinafter with a broken line in another cross section.

The semiconductor module S2 according to the present embodiment is different from the one in the first embodiment such that two heat-transfer insulated substrate 7 are respectively disposed between the first heat sink 1 and the semiconductor device 2 and between the semiconductor device 2 and the second heat sink 3. The following describes the difference between the present embodiment and the first embodiment.

As illustrated in FIG. 7, in the heat-transfer insulated substrate 7, an electrical conductor 71, an insulator 72 and a thermal conductor 73 are stacked in this order. In one of the heat-transfer insulated substrate 7, the electrical conductor 71 is connected to the semiconductor device 2 through the bonding member 5, and the thermal conductor 73 is connected to the first heat sink 1 through, for example, solder (not shown). In the other one of the heat-transfer insulated substrate 7, the electrical conductor 71 is connected to the semiconductor device 2 through the bonding member 5, and the thermal conductor 73 is connected to the first heat sink 1 through, for example, solder (not shown).

In the heat-transfer insulated substrate 7, any one of the electrical conductor 71, the insulator 72 and the thermal conductor 73 is made of material with higher thermal conductivity; however, the electrical conductor 71 and the thermal conductor 73 are electrically isolated by the insulator 72. Through the heat transfer insulating substrate 7, the semiconductor module S2 has a configuration in which the semiconductor device 2 is electrically independent of the first heat sink 1 and the second heat sink 3, but is thermally connected. In other words, in the semiconductor module S2 according to the present embodiment, the first heat sink member includes the first heat sink 1 and the heat-transfer insulated substrate 7, and the second heat sink member includes the second heat sink 3 and the thermal insulated substrate 7. The heat-transfer insulated substrate 7 is connected to the semiconductor device 2.

For example, in the heat-transfer insulated substrate 7, the electrical conductor 71 is mainly made of metal material such as copper, the insulator 72 is mainly made of insulating material such as aluminum oxide or aluminum nitride, and the thermal conductor 72 is mainly made of metal material such as copper. For example, a direct bonded copper (DBC) substrate is adopted as the heat-transfer insulated substrate 7.

A part of the electrical conductor 71 of the heat-transfer insulated substrate 7 may be wired and connected to, for example, an external power supply, or may be connected by other wiring such as the lead frame 4 and have electrical communication with the semiconductor element 20.

Since the heat sink block 102 and the wire 103 are not necessary in the present embodiment, the advantageous effects similar to the first embodiment may be attained.

In the semiconductor module S2, the semiconductor device 2 and the heat sinks 1, 3 are insulated by the heat-transfer insulated substrate 7. When the semiconductor module S2 is connected to, for example, an external cooler, an insulating later is not required to be additionally provided between the cooler and the semiconductor module S2. Therefore, the semiconductor module S2 has an enhanced reliability when connecting to, for example, the external cooler.

### Third Embodiment

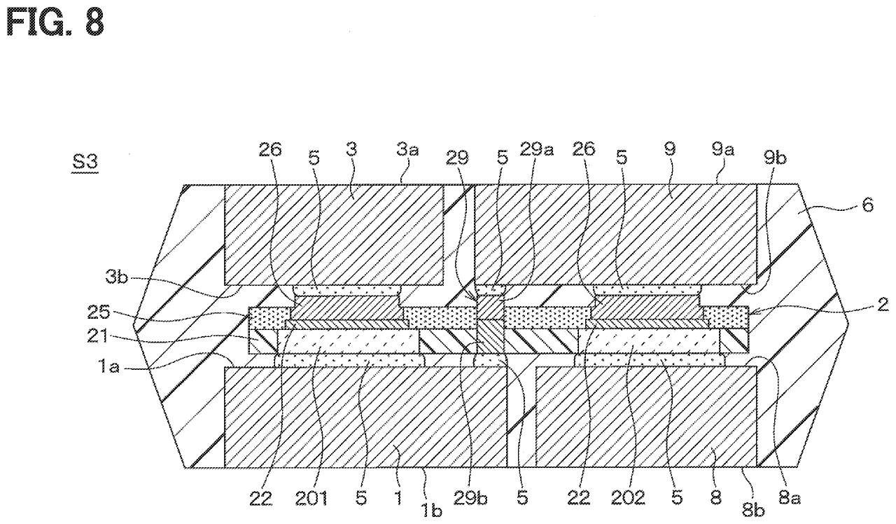

The following describes a semiconductor module S3 according to the third embodiment with reference to FIGS. 8 to 10.

As illustrated in FIG. 8, the present embodiment is different from the first embodiment such that, in the semiconductor module S3 according to the present embodiment, the semiconductor device 2 includes two semiconductor elements 20 and a relay member 29, and further includes heat sinks 8, 9 in addition to the heat sink 1, 3. The following describes the difference between the present embodiment and the first embodiment.

In the present embodiment, the semiconductor device 2 includes two portions, each of which has a semiconductor element 20 with a variety of electrodes and the first wiring 26 and the second wiring 27 formed on the semiconductor element 20. Hereinafter, these two portions are simply referred to as two element portions. The semiconductor device 2 has the relay member 29 penetrating between two portions in the thickness direction.

In the following description, for the simplicity of explaining two semiconductor elements 20, one of the semiconductor element 20 connected to the heat sinks 1, 3 is referred to as a first semiconductor element 201, and the other one of the semiconductor element 20 connected to the heat sinks 8, 9 is referred to as a second semiconductor element 202, as illustrated in FIG. 8. The following describes that these semiconductor elements 201, 202 have the identical structures.

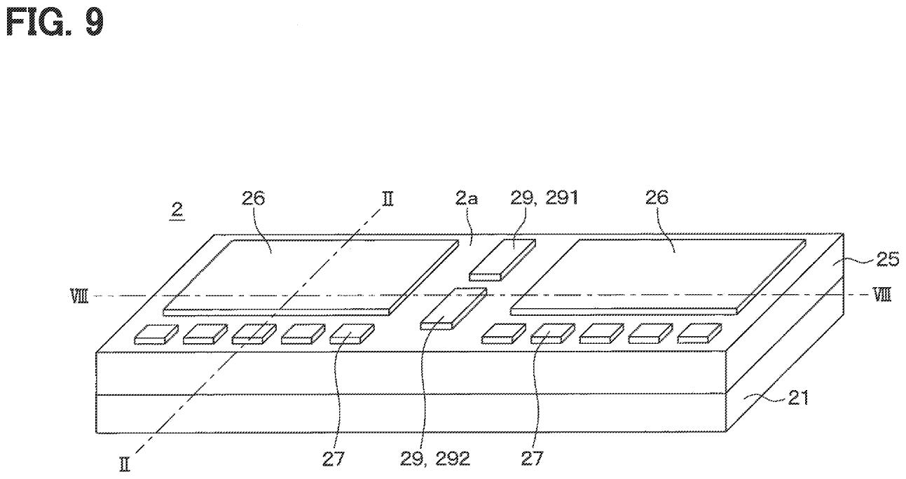

As illustrated in FIG. 9, the first semiconductor element 201 and the second semiconductor element 202 respectively have, for example, the first wiring 26 and multiple second wirings 27, and the two element portions are aligned and oriented in the same direction. The cross-sectional structure and the connection with the heat sinks 1, 3 between II-II indicated by a one-dotted chain line in FIG. 9 are similar to the semiconductor device 2 in the first embodiment.

For example, as illustrated in FIG. 8, the relay member 29 includes a first member 29a and a second member 29a. The relay member 29 is a member electrically connected to the heat sink and a member different from the heat sink in the thickness direction of the semiconductor device 2. The relay member 29 is made of, for example, metal material such as copper, and is formed by electroplating. For example, a copper pillar is disposed as the second member 29b between the separated semiconductor elements 201 and 202, and these semiconductor elements 201 and 202 are covered by the sealing member 21. In the example illustrated in FIG. 8, the dimension of the second member 29b in the thickness direction is identical to the semiconductor elements 201, 202 formed with the first electrode 22, and the second member 29b is exposed with the surface of the semiconductor elements 201, 202 at a side where the first electrode 22 is formed. At the formation of the rewiring layer 24, it is possible to extend the first member as a remaining part on the copper pillar with the method identical to the one used for the rewiring layer 24 to form the relay member 29. The pillar covered with the sealing member 21 may be made of conductive material, or may be made of material other than copper. For example, as illustrated in FIG. 8, the relay member 29 is used for connecting the first heat sink 1 and the fourth heat sink 9, and is a current path between two semiconductor elements 20. In the example illustrated in FIG. 8, the relay member 29 is disposed at a portion of the semiconductor device 2 exposed from the second heat sink 3, and is disposed inside the outline of the first heat sink 1. An example of the planar layout of the relay member 20 is described hereinafter.

As illustrated in FIG. 8, the third heat sink 8 is a plate having an upper surface 8a and a lower surface 8b, and is made of metal material such as copper, as similar to the first heat sink 1. The upper surface 8a may also be referred to as a main surface, and the lower surface 8b may also be referred to as a rear surface. The third heat sink 8 is disposed separately from the first heat sink 1 with a predetermined distance or larger so as to not to be directly connected to the first heat sink, in other words, not to be short-circuited. In other words, the third heat sink 8 is disposed to be separated from the first heat sink 1 across the sealing member 6, while facing the rear surface 2b of the semiconductor device 2 facing the first heat sink 1. The third heat sink 8 may also be referred to as a “third heat sink member”.

As illustrated in FIG. 8, the fourth heat sink 8 is a plate having a first surface 9a and a second surface 9b, and is made of metal material such as copper, as similar to the first heat sink 1. The first surface 9a may also be referred to as a main surface, and the second surface 9b may also be referred to as a rear surface. The second surface 9b of the fourth heat sink 9 is disposed to face the element portion having the second semiconductor element 202 of the semiconductor device 2, and is electrically connected to the second semiconductor element 202 through the bonding member 5. The first surface 9a of the fourth heat sink 9 is exposed from the sealing member 6. The fourth heat sink 9 is disposed to be separately from the second heat sink 3 with a predetermined distance or larger so as to not to be directly connected to the second heat sink, in other words, not to have the short-circuit. In other words, the fourth heat sink 9 is disposed to be separated from the second heat sink 3 across the sealing member 6, while facing the main surface 2a of the semiconductor device 2 facing the second heat sink 3. The fourth heat sink 9 may also be referred to as a “fourth heat sink member”.

The element portion having the second semiconductor element 202 of the semiconductor device 2 is disposed inside the outline of the upper surface 8a of the third heat sink 8. One end of the second wiring 27 in the element portion is disposed outside of the outline of the second surface 9b of the fourth heat sink 9, and is bonded to the lead frame 4 with solder in another cross section of FIG. 8.

In other words, the semiconductor module S3 according to the present embodiment includes two element portions as a double-sided heat sink structure inside the sealing member 6, and these element portions are electrically connected in series through the relay member 29. Such a semiconductor module S3 may be referred to as a “2 in 1 structure.

The following describes an example of the planar layout of the four heat sinks 1, 3, 8, 9 and the relay member 29.

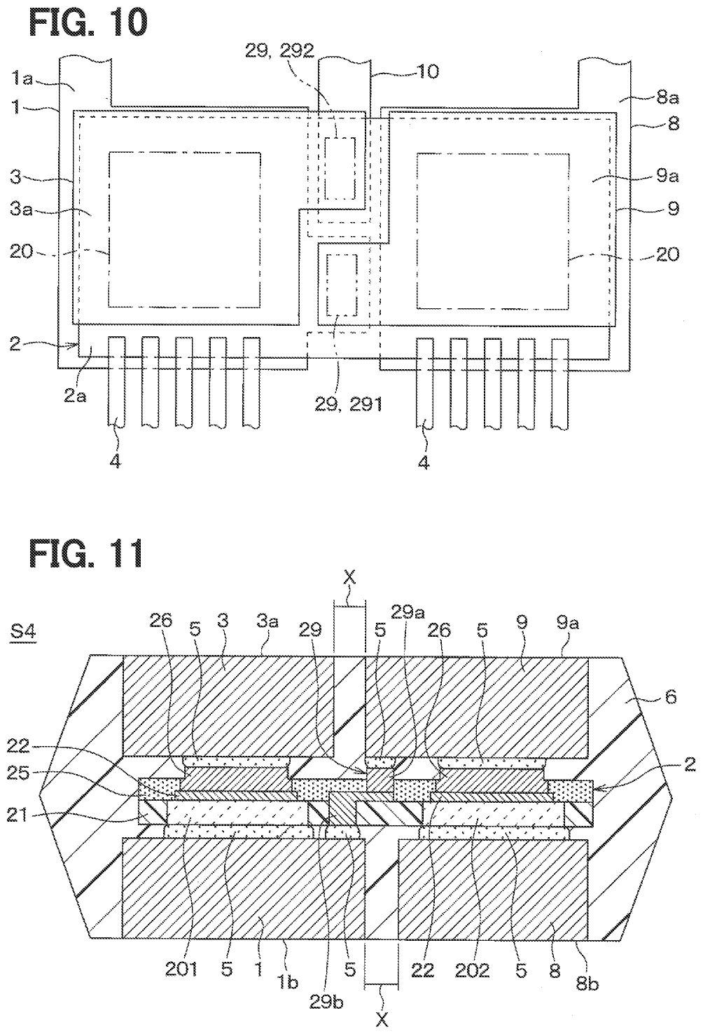

For example, as illustrated in FIG. 10, in the semiconductor module S3, the semiconductor device 2 having two semiconductor elements 20 is disposed between the heat sinks 1 and 3 facing to each other and between the heat sinks 8 and 9 facing to each other. The semiconductor module S3 further includes a fifth heat sink 10, which is disposed between the first heat sink 1 and the third heat sink 8 and is electrically connected to the second heat sink 3 through the relay member 29.

The semiconductor device 2 has two relay members 291 and 292. For example, as illustrated in FIG. 10, the first relay member 291 is disposed in a portion where the first heat sink 1 and the fourth heat sink 9 are overlapped with respect to the first surface 3a viewed in a normal direction, and the respective heat sinks are connected through the bonding member 5. The second relay member 292 is disposed in a portion where the second heat sink 3 and the fifth heat sink 10 are overlapped with respect to the first surface 3a viewed in a normal direction, and the respective heat sinks are connected through the bonding member 5. In the semiconductor module S3 having such a layout, the current value is appropriately changed by switching on and off the two semiconductor elements 20.

As illustrated in FIG. 10, the lead frames 4 are connected to the second wiring 27 (not shown) formed at the two element portions at the outer side of the respective outlines of the second heat sink 3 and the fourth heat sink 9. Therefore, even if the structure is 2in1 as in the present embodiment, the heat sink block 102 and the wire 103 are unnecessary, and the thickness and the thermal resistance are reduced as compared with the comparative structure.

According to the present embodiment, the same advantageous effect as that of the fourth embodiment is achieved.

(Modification of Third Embodiment)

The following describes a semiconductor module S4 according to the modification of the third embodiment with reference to FIG. 11. The semiconductor module S4 is different from the third embodiment such that the cross sectional shape of the relay member 29 is modified as illustrated in FIG. 11.

The relay member 29 has a shape having at least one stepped portion in a cross sectional view in the present modification. The stepped portion may also be referred to as a step. As illustrated in FIG. 11, the relay member 29 has a shape such that the second member 29b has a stepped portion, and the first member 20a is extended at a different position. Therefore, the portion of the semiconductor device 2 exposed from the main surface 2a and the portion of the semiconductor device 2 exposed from the rear surface 2b are offset. The relay member 29 is formed by the above-mentioned method described in the third embodiment. For example, a portion of the copper pillar having the stepped portion as the second member 29b is covered by the sealing member 21. As in the third embodiment, the second member 29b has a surface at the side of the semiconductor elements 201, 202 on which the first electrode 22 is formed, and has a surface at the same side exposed from the sealing member 21. In a plan view, the first member 29a is extended in the thickness direction as similar to the rewiring layer 24 at a position offset from the portion of the copper pillar exposed from the rear surface 2b. The relay member 29 has a shape with the stepped portion, and the portion exposed from the main surface 2a and the portion exposed from the rear surface 2b are offset. In the present modification, the pillar covered by the sealing member 21 may be columnar or may have a shape having a stepped portion (for example, an L-shape in a cross sectional view), which may be arbitrary. In a situation where the pillar is columnar, the relay member 29 is formed by forming a portion protruding from the outline of the pillar in a plan view and then extending a remaining part on the protruding portion in the thickness direction. In a situation where the relay member 29 has the stepped portion, the relay member 29 is the surface at the side where the rewiring layer 24 of the pillar is formed, and the relay member 29 is formed by extending the remaining part at a position offset from the exposed portion of the sealing member 21 at the rear side in the thickness direction. According to the above-mentioned method, the relay member 29 is formed so that the portion of the semiconductor device 2 exposed from the main surface 2a and the portion of the semiconductor device 2 exposed from the rear surface 2b are offset, and the relay member 29 has a cross sectional shape having at least one stepped portion. As a result, not only the advantageous effect in reducing the thickness but also the effect in reducing the planar size can be attained.

In a situation where the cross sectional shape of the relay member 29 is rectangular as in the third embodiment, in order to prevent from having the short-circuit between the relay member 29 and the second heat sink 3, it is required to enlarge the width of the first heat sink 1 to be larger than the second heat sink 3. As illustrated in FIG. 11, the distance between the first heat sink 1 and the third heat sink 8 and the distance between the second heat sink 3 and the fourth heat sink 9 are required to be X or larger in view of the prevention of having a short-circuit between them. In the third embodiment, the width of the first heat sink 1 is the distance X between the second heat sink 3 and the at least the fourth heat sink 9 and spacing for connecting the relay member 29.

In contrast, in the present modification, the relay member 29 has a shape bent in the semiconductor device 2, and has a portion connected to the fourth heat sink 9. The portion connected to the fourth heat sink 9 and the portion connected to the first heat sink 1 are offset against to each other. As a result, as illustrated in FIG. 11, even though one end of the relay member 29 is connected to a portion of the first heat sink 1 that protrudes from the second heat sink 3 by the width of X, the other end of the relay member 29 offset against the one end of the relay member 29 can be connected to the fourth heat sink 9.

Therefore, in the present modification, the width of the first heat sink 1 can me made smaller than the width described in the third embodiment. The fourth sink 9 is connected by the other end of the relay member 29. With the identical reason, it is not required for the fourth heat sink 9 to have an extra width as compared with the third heat sink 8, and it is possible to reduce the width as compared with the third embodiment. As a result, the planar size of the semiconductor module S4 can be made smaller as compared with the third embodiment by reducing the width of the first heat sink 1 and the fourth heat sink 9.

According to the present modification, in addition to the identical effect as that of the third embodiment, the semiconductor module S4 has an advantageous effect in miniaturizing the planar size.

### Fourth Embodiment

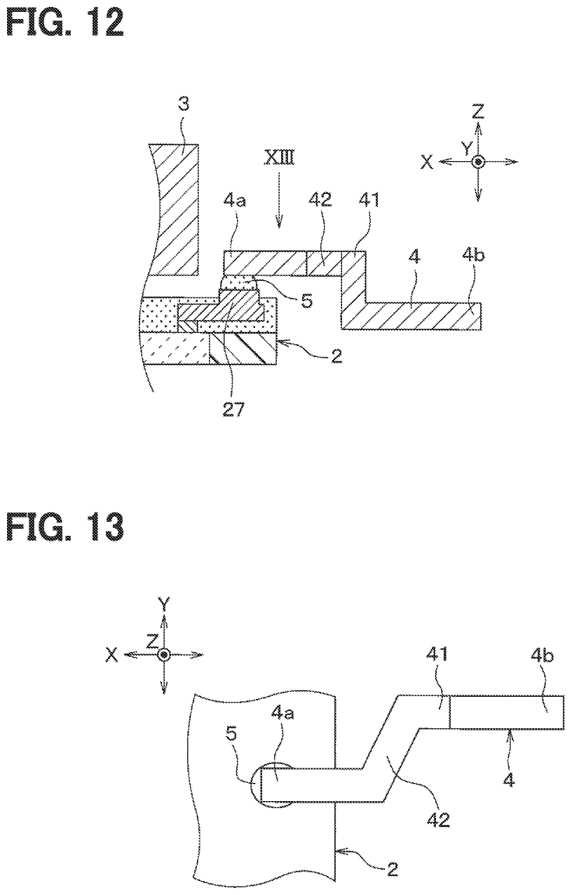

The following describes a semiconductor module according to the fourth embodiment with reference to FIGS. 12, 13.

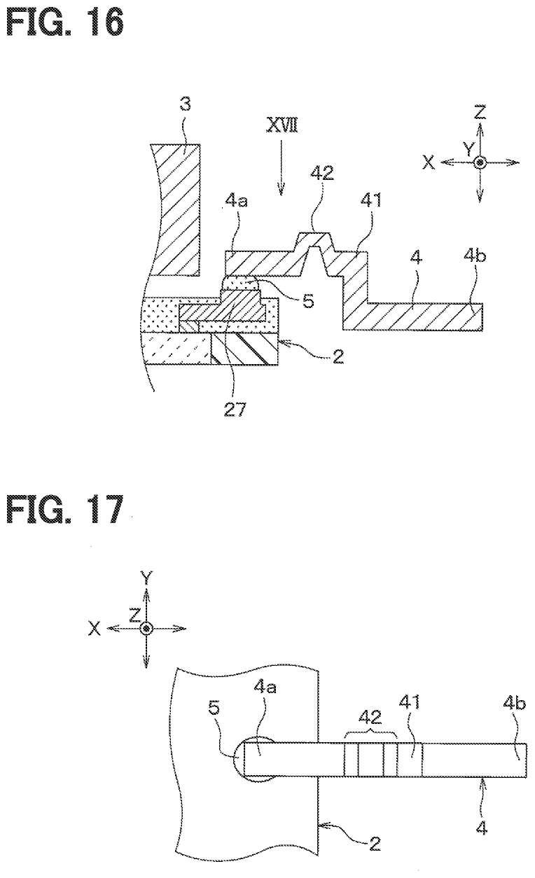

FIG. 12 omits a part other than a portion of the semiconductor device 2, a portion of the heat sink 3 and the lead frame 4 as the configuration elements in the semiconductor module according to the present embodiment for clearly illustrating a stress relaxing portion 42 of the lead frame 4. A direction along a left-right direction of the drawing sheet of FIG. 12 is denoted as an X-direction, a direction perpendicular to the drawing sheet of FIG. 12 is denoted as a Y-direction, and a direction perpendicular to the X-direction in the drawing sheet of FIG. 12 is denoted as a Z-direction. The X, Y and Z-directions are indicated by respective arrows. The same applies to FIG. 16.

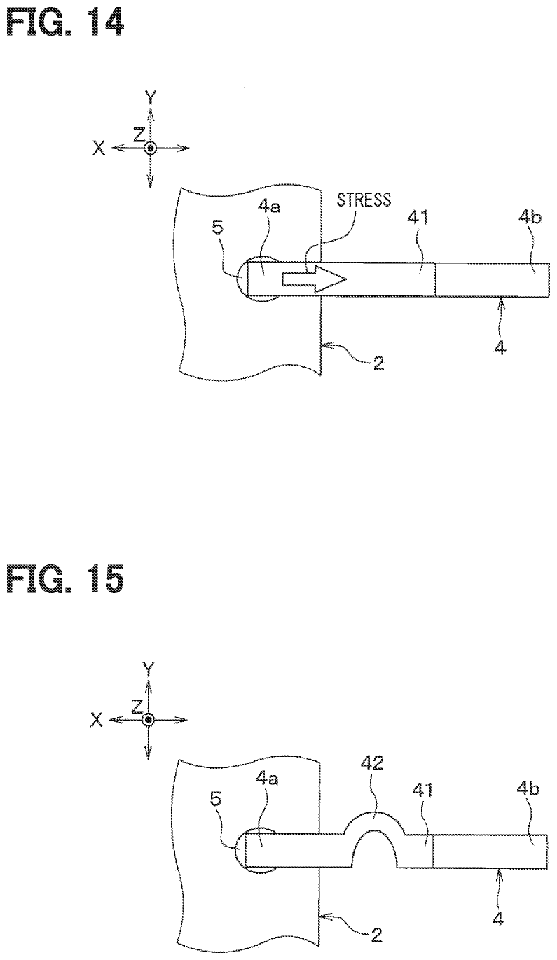

With the similar reason as in FIG. 12, FIG. 13 omits members other than a portion of the semiconductor device 2, the lead frame 4, and the bonding member, and each of the X, Y and Z-directions indicated in FIG. 12 are indicated by arrows. The same applies to FIGS. 14, 15 and 17.

For example, as illustrated in FIG. 12, the semiconductor module according to the present embodiment is different from the one described in the first embodiment such that the semiconductor module according to the present embodiment has a configuration in which the lead frame connected to the second wiring 27 of the semiconductor device 2 through the bonding member 5 has the stress relaxing portion 42. The following describes the difference between the present embodiment and the first embodiment.

As illustrated in FIG. 12, the end portion of the lead frame 4 connected to the second wiring 27 is referred to as a first end portion 4a, and the other end portion opposite to the first end portion 4a is referred to as a second end portion 4b. The direction from the first end portion 4a to the second end portion 4b along the lead frame 4 is referred to as an extending direction.

In the present embodiment, the lead frame 4 has the stress relaxing portion 42 for relieving the stress generated at the first end portion 4a of the lead frame 4 in the manufacturing process, and for reducing the load applied to the bonding member 5 connecting the second wiring 27 and the lead frame 4. The cooling process in the process of manufacturing the semiconductor module is after connecting the lead frame 4 to the second wiring through the bonding member 5. In the cooling process, a stress is applied to the first end portion 4a because of the thermal expansion of the lead frame 4, and the load is applied to the bonding member 5 due to the stress. Since cracks may occur in the bonding member 5 due to this load, it may be preferable to reduce the stress generated on the first end portion 4a in view of ensuring the bonding reliability. In other words, the stress is concentrated on the stress relaxing portion 42 and the location receiving the stress is deformed elastically or plastically. Therefore, the stress and the load applied to the bonding member are reduced, so that the generation of cracks on the bonding member 5 is prevented.

For example, as illustrated in FIG. 12, the lead frame 4 has a shape with a boundary portion 41 as a boundary part whose extending direction changes between the first end portion 4a and the second end portion 4b. For example, the lead frame 4 has a shape in which a part including the first end portion 4a and a part including the second end portion 4b are long the X-direction, and a part between the first end portion 4a and the second end portion is along the Z-direction. In this situation, the extending direction of the lead frame 4 from the X-direction to the Z-direction, and the boundary is the boundary portion 41.

A part of the lead frame 4 between the first end portion 4a and the boundary portion 41 is a stress relaxing portion 42 whose extending direction is different from the extending direction of the other portions. For example, as illustrated in FIG. 13, in the lead frame 4, the extending direction of a predetermined portion including the first end portion 4a is along the X-direction; however, the extending direction of the stress relaxing portion 42 is changed in the Y-direction on the way to the boundary portion 41. In other words, in the present embodiment, the lead frame 4 has a substantially L-shaped portion from the first end portion 4a to the boundary portion 41 with the arrangement of the stress relaxing portion 42. The lead frame 4 has a flat shape in which the portion from the first end portion 4a to the boundary portion 41 and the portion from the second end portion 4b to the boundary portion 41 are not arranged in an identical linear shape. In other words, the lead frame 4 has a portion from the first end portion 4a to the boundary portion 41 has a shape different from the linear shape.

In a situation where the portion from the first end portion 4a to the boundary portion 41 has the linear shape, the lead frame 4 has thermal contraction along the extending direction and the stress occurs as indicated by a white arrow in FIG. 14 in the cooling process after connecting the lead frame 4 to the semiconductor device 2 through the bonding member 5. In a situation where the thermal stress is larger, cracks may occur at the bonding member 5 and the reliability of the semiconductor module may decrease. The stress relaxing portion 42 relieves the thermal stress applied on the bonding member 5 by changing the extending direction at the portion from the first end portion to the boundary portion 41. The stress relaxing portion 42 is formed, for example, by performing a press punching process on a plate material made of a metal material.

According to the present embodiment, in addition to the advantageous effects described in the first embodiment, it is possible to suppress the cracks occurred at the bonding member 5 for connecting the second wiring 27 of the semiconductor device 2 and the lead frame 4, and further enhance the reliability.

(Modification of Fourth Embodiment)

The stress relaxing portion 42 may have a structure for relieving the stress occurred at the first end portion 4a. However, it may not only limited to this example. For example, as illustrated in FIG. 15, the stress relaxing portion 42 may have a substantially U-shape on the XY plane in a top view.

For example, as illustrated in FIG. 16, the stress relaxing portion 42 may have a substantially U-shape deformed in the Z-direction in the cross sectional view. For example, as illustrated in FIG. 17, the lead frame 4 has a portion from the first end portion 4a to the boundary portion 41 and a portion from the second end portion 4b to the boundary portion 41 arranged on the identical straight line in a top view. Since the extending direction of the lead frame 4 changes on the way from the boundary portion 41 to the first end portion 4a by the stress relaxing portion 42, the thermal stress generated at the first end portion 4a is reduced in the cooling process after connecting to the semiconductor device 2.

The stress relaxing portion 42 may be formed so as to be located on the identical plane as the portion from the first end portion 4a to the boundary portion 41 in view of the accuracy in manufacturing. In order to concentrate the stress on the stress relaxing portion 42 and elastically or plastically deform the stress relaxing portion 42, as described above, the stress relaxing portion 42 may not be directed to the extending direction of the lead frame 4, but the width or thickness may be partially different from other portions. In other words, the stress relaxing portion 42 is a portion between the first end portion 4a and the boundary portion 41 in which at least one of the thickness, width and extending direction of the lead frame 4 is different from other parts. The width of the lead frame 4 described herein may be referred to as the dimension of the lead frame in a direction perpendicular to the extending direction.

According to this modification, the same effect as that of the fourth embodiment can be obtained.

### Fifth Embodiment

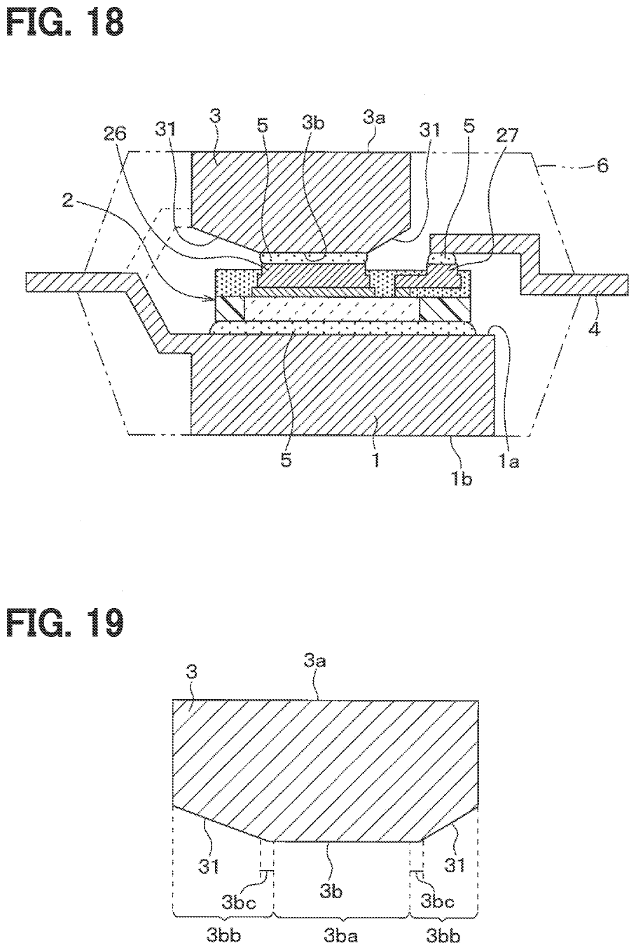

The following describes a semiconductor module according to the fifth embodiment with reference to FIGS. 18 to 20.

For illustrating a recessed portion 31 formed at the second heat sink 3, FIG. 18 omits the sealing member 6 and indicates the outline of the sealing member 6 with a two-dotted chain line.

For example, as illustrated in FIG. 18, the semiconductor module according to the present embodiment is different from the first embodiment such that the recessed portion 31 is formed at the second surface 3b of the second heat sink 3 connected to the first wiring 26 of the semiconductor device 2. The following describes the difference between the present embodiment and the first embodiment.

In the present embodiment, the second heat sink 3 has the recessed portion 31. The recessed portion 31 is recessed towards the first surface 3a at a region different from a region of the second surface 3b connected to the first wiring 26 of the semiconductor device 2. The second heat sink 3 ensures the gap between the semiconductor device 2 and the second heat sink 3. As illustrated in FIG. 19, the second heat sink 3 includes the second surface 3b having a bonding region 3ba and a non-bonding region 3bb. The bonding region 3ba is bonded to the semiconductor device 2, and the non-bonding region 3bb is an outer region of the second surface 3b with respect to the bonding region 3ba. At least one portion of the non-bonding region 3bb is the recessed portion 31.

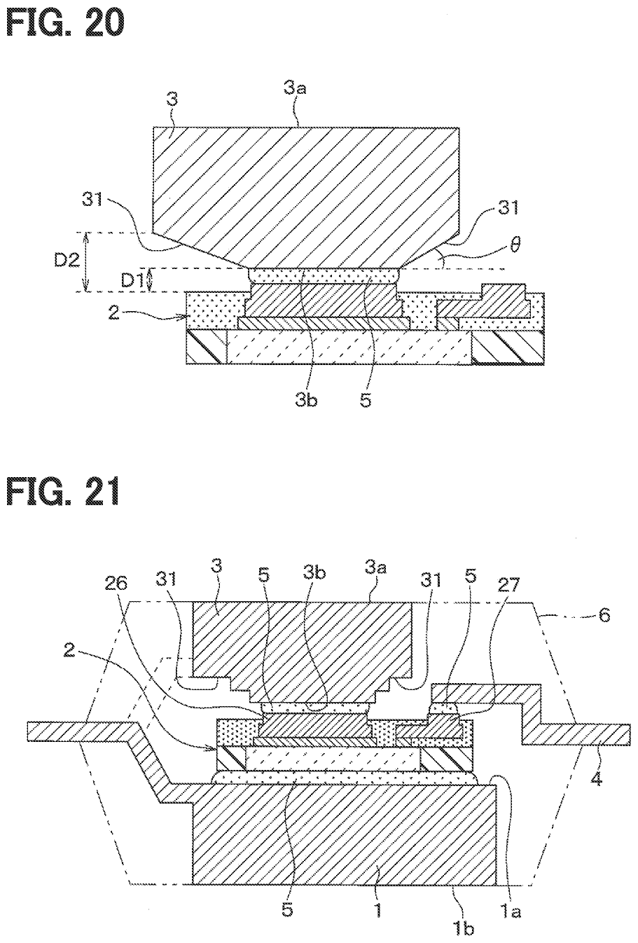

For example, the recessed portion 31 has a tapered shape inclined from the end portion of a bonding vicinity region 3bc towards the outline of the second surface 3b. A part of the non-bonding region 3bb located at a vicinity of the bonding region 3ba is regarded as the bonding vicinity region 3bc. The recessed portion 31 may be formed by any processing method such as pressing, cutting, casting or etching. For example, as illustrated in FIG. 20, the recessed portion 31 may be formed with a taper angle θ being 45 degrees or smaller. The taper angle θ is defined as an acute angle formed between an inclined surface being a surface formed at the recessed portion 31 and an inclined surface being the surface formed at the bonding region 3ba. This is for securing a region of the second heat sink 3 for diffusing the thermal conduction from the semiconductor device 2 outwards to prevent from lowering the heat sink ability of the semiconductor device 2.

The recessed portion 31 has a shape such that the gap D2 is larger than the gap D1. The gap D2 of the non-bonding region 3bb is formed with the semiconductor device 2 at the outline of the second surface 3b, and the gap D1 is formed with the semiconductor device 2 at the bonding vicinity region 3bc. This facilitates the flow of the sealing member into the gap between the semiconductor device 2 and the second heat sink 3 for securing the filling property of the sealing member in the formation of the sealing member 6.

For example, in a situation where the entire second surface 3b is a flat surface, the thickness of the bonding member 5 is 100 micrometers or less. When the sealing member containing the filler is poured, the filler may be difficult to enter the gap between the semiconductor device 2 and the second heat sink 3 and voids may occur. In a situation where such a void occurs at the sealing member 6, when the heating and cooling cycle in the semiconductor module is repeated, the action of relieving the thermal stress in the bonding member 5 is weakened, and the cracks may occur. Thus, the reliability of the semiconductor module may not be ensured.

In contrast, in the present embodiment, the second heat sink 3 includes the recessed portion 31 at the second surface 3b, and the gap between the semiconductor device 2 and the second heat sink 3 is widened outwards from the bonding vicinity region 3bc. Therefore, even in a situation where the thickness of the bonding member 5 is smaller and the bonding member containing the filler is adopted, the sealing member easily flows into the gap between the semiconductor device 2 and the second heat sink 3 and the filling ability is enhanced. Thus, the generation of voids at the sealing member 6 is suppressed.

According to the present embodiment, in addition to the advantageous effects described in the first embodiment, the semiconductor module generates advantageous effects in enhancing the filling ability of the sealing member 6 at the gap between the semiconductor device 2 and the second heat sink 3, suppressing the generation of the voids at the sealing member 6 and further enhancing the reliability.

(Modification of Fifth Embodiment)

The recessed portion 31 of the second heat sink 3 may have a shape such that the resin material included in the sealing member 6 is filled into the gap between the semiconductor device 2 and the second heat sink 3. However, it is not only restricted to this example. For example, as illustrated in FIG. 21, the recessed portion 31 may have a staircase shape. Even in this situation, the gap formed at the non-bonding region 3bb of the second surface 3b of the second heat sink 3 with respect to the semiconductor device 2 is relatively large at the outer edge portion of the second surface 3b as compared with the bonding vicinity region 3bc. Therefore, the filling ability of the sealing member in the gap between the semiconductor device 2 and the second heat sink 3 can be ensured.

According to this modification, the same effect as that of the fifth embodiment can be obtained.

### Sixth Embodiment

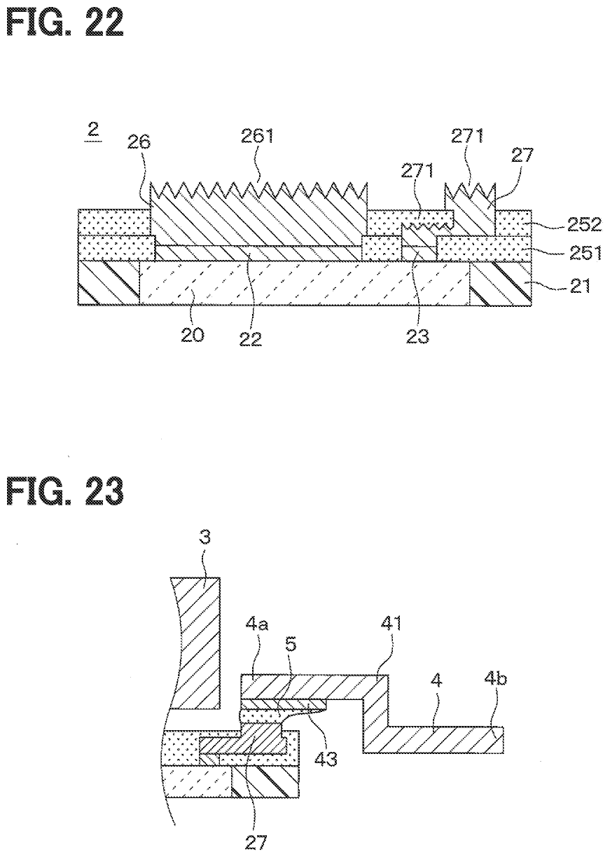

The following describes a semiconductor module according to the sixth embodiment with reference to FIG. 22.

For example, as illustrated in FIG. 22, the semiconductor module according to the present embodiment is different from the first embodiment such that the semiconductor module according to the present embodiment has roughened portions 261, 271. The roughened portions 261, 271 are respectively portions of the first wiring 26 and the second wiring 27 in the semiconductor 2 that are roughened. The following describes the difference between the present embodiment and the first embodiment.

In the present embodiment, as illustrated in FIG. 22, a portion of the first wiring 26 exposed from the insulating layer 25 included in the rewiring layer 24 is roughened as the roughened portion 261. In the present embodiment, a portion of the second wiring 27 covered by the insulating layer 25 and a portion exposed from the insulating layer 25 are roughened as the roughened portion 271. The roughened portions 261, 271 may be formed by a roughening plating method described in JP 2019-181710 A or any arbitrary method such as a method of roughening through a post-treatment process such as laser irradiation after the formation of the wiring through a plating formation process.

Compared with a situation where the roughened portions 261, 271 are not roughened, the specific surface area at the interface between the bonding member 5 and the insulating layer 25 is enlarged, and the adhesion with the contacting material is enhanced. Therefore, the reliability of the semiconductor module is enhanced.

The term “roughened portion” as described herein means that, for example, the calculated average surface roughness Ra (unit: micrometer) defined by the Japanese Industrial Standards (JIS) is 0.3 or more.

According to the present embodiment, in addition to the advantageous effects described in the first embodiment, the semiconductor module has advantageous effects in enhancing the adhesion of the second wiring in the rewiring layer 24 of the semiconductor device 2 and the adhesion between the wirings 26, 27 and the bonding member 5 and further enhancing the reliability of bonding.

### Seventh Embodiment

The following describes a semiconductor module according to the seventh embodiment with reference to FIG. 23.

FIG. 23 omits a part other than a portion of the semiconductor device 2, a portion of the heat sink 3 and the lead frame 4 as the configuration elements in the semiconductor module according to the present embodiment for easily viewing a cover layer 43 of the lead frame 4.

The semiconductor module according to the present embodiment is different from the first embodiment in that the cover layer 43 is provided at the lead frame 4 in the present embodiment. The following describes the difference between the present embodiment and the first embodiment.

In the present embodiment, the lead frame 4 includes the cover layer 43 that covers a predetermined region including a portion of region at the first end portion 4a, in other words, a portion connected to the second wiring 27. When the lead frame 4 is connected to the second wiring 27 through the bonding member 5, the cover layer 43 is formed to prevent from the molten bonding member 5 protruding into an unintended region and generating the short-circuit between the lead frame 4 and the unintended region. For example, when the bonding member 5 is coated on the semiconductor device 2 and the molten bonding member 5 is protruded to the second heat sink 3, the protruded bonding member 5 is directly connected to the second heat sink 3 and the lead frame 4 and forms the short-circuit. The cover layer 43 suppresses wet spreading of the bonding member 5 to such an unintended region.

The cover layer 43 controls a direction of the wetting spread of the molten bonding member 5 by having an arbitrary material having the wettability of the bonding member 5 higher than that of the lead frame 4. For example, in a situation where the lead frame 4 is made of copper and the bonding member 5 is made of solder, the cover layer 43 is made of, for example, gold, silver, tin, or an alloy of the gold, silver and tin. The cover layer 43 is formed by an arbitrary method such as vapor deposition or sputtering.

A portion of the second wiring 27 exposed from the insulating layer is defined as an exposing portion. A portion of the lead frame 4 opposed to the exposed portion of the second wiring 27 is an opposing portion. The cover layer 43 continuously covers a predetermined region at the second end portion 4b from the opposing portion. As a result, when the molten bonding member 5 is in contact with the cover layer 43, since the bonding member 5 gets wet and spreads the wet towards the second end portion 4b along the cover layer 43, the protruding of the bonding member 5 towards the second heat sink 3 is inhibited.

According to the present embodiment, in addition to the advantageous effects described in the first embodiment, the semiconductor module has advantageous effects in preventing the bonding member 5 flowing into an unintended direction in the manufacturing process and suppressing insulation defects.

The above describes an example of the manufacturing process for connecting the lead frame 4 having the cover layer 43 after coating the bonding member 5 on the semiconductor device 2. However it is not only restricted to this manufacturing process. The bonding member 5 may be coated on the rear surface 2b of the semiconductor device 2 and the first wiring 26 and the second wiring 27 in advance, and the lead frame 4 having the cover layer 43 may be connected to the semiconductor device 2. In this situation, it is possible that the semiconductor device 2, the first heat sink 1, the second heat sink 3 and the lead frame 4 can be bonded together, and the manufacturing process may be simplified.

The lead frame 4 may have a structure for suppressing the wetting and spreading of the bonding member 5. The lead frame 4 may also have a structure without the cover layer 43. For example, the lead frame 4 may have a structure for suppressing the wetting and spreading of the bonding member 5 by deteriorating the wettability a region corresponding to the cover layer 43 as compared with other regions, without the formation of the cover layer 43. For example, laser irradiation may be applied for partially deteriorating the wettability to the bonding member 5 in the lead frame. In other words, the lead frame 4 has a region where the wettability to the bonding member 5 is relatively high and a region where the wettability to the bonding member 5 is relatively low. The region with relatively high wettability to the bonding member 5 is extended from the first end portion 4a to the second end portion 4b. The same applies to the modification of the present embodiment.

(Modification of Seventh Embodiment)

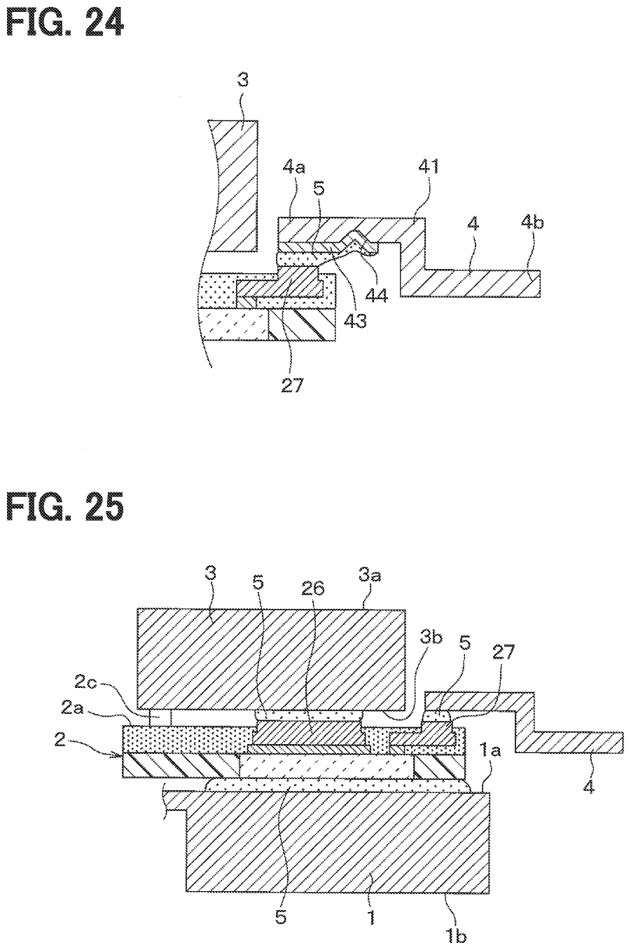

For example, as illustrated in FIG. 24, the lead frame 4 may have a groove 44 formed closer to the second end portion 4b than the opposing portion facing the second wiring 27 and at a predetermined distance from the opposing portion. In this situation, the cover layer 43 is formed to cover a region of the lead frame 4 from at least the opposing portion to the groove 44.

For example, as illustrated in FIG. 24, the groove 44 absorbs an excess amount of the bonding member 5 when the excess amount of the bonding member 5 is coated on the second wiring 27, and prevents the bonding member 5 from flowing to the unintended region. The groove 44 is formed into a substantially V-shaped groove by an arbitrary processing method such as V-groove processing or half-etching method, but the shape may be any shape as long as the excess amount of the bonding member 5 can flow into the groove. The shape or the depth of the groove 44 is arbitrary. If the groove 44 is too far from the opposing portion, it becomes difficult to absorb the excess amount of the bonding member 5. Thus, for example. The groove 44 is formed within a predetermined range from the opposing portion, and is formed closer to the first end portion 4a than the boundary portion 41.

According to the modification, even if the excessive bonding member 5 is coated on the semiconductor device 2, the semiconductor module has the advantageous effects in absorbing the excessive amount of the bonding member 5 and preventing the bonding member 5 from protruding to the unintended region. Thus, the semiconductor module according to the modification further enhance the advantageous effects described in the seventh embodiment.

### Eighth Embodiment

The following describes a semiconductor module according to the eighth embodiment with reference to FIGS. 25 to 27.

FIG. 25 omits a portion of the first heat sink 1 and the sealing member 6 for clearly illustrating a protrusion 2c.

For example, as illustrated in FIG. 25, the semiconductor module according to the present embodiment is different from the first embodiment in that the semiconductor module according to the present embodiment has the protrusion 2c at the semiconductor device 2, and the semiconductor device 2 and the second heat sink are not in contact to each other at an unintended location. The following describes the difference between the present embodiment and the first embodiment.

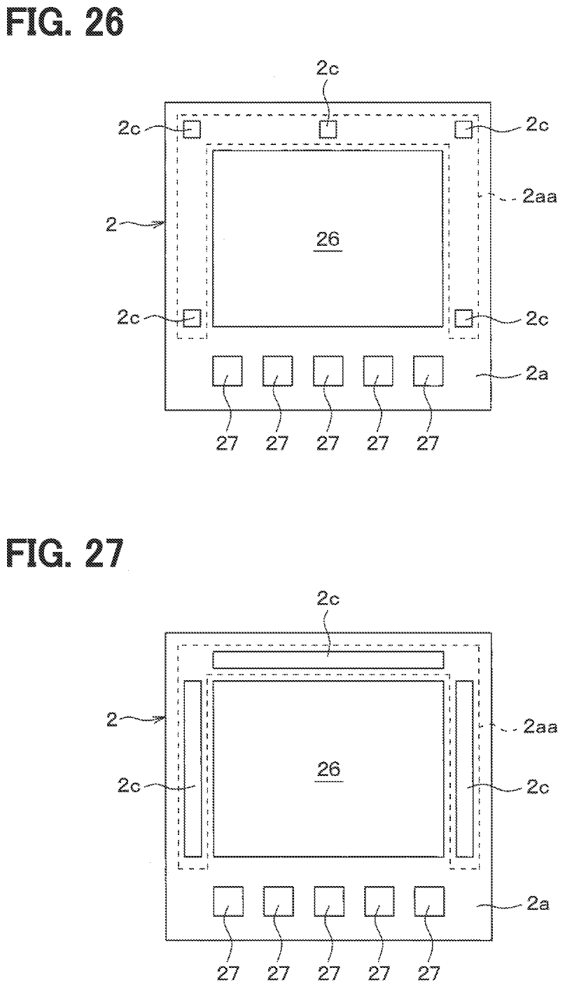

For example, as illustrated in FIG. 26, in the present embodiment, the semiconductor device 2 includes multiple protrusions 2c in a region at a vicinity of the outline of the main surface 2a near the first wiring 26. In a situation where the end portion of the semiconductor device 2 is warped towards the second heat sink 3 in the manufacturing process, it is possible to prevent the poor filling of the sealing member 6 caused by a contact between the main surface 2a of the semiconductor device 2 and the end portion of the second surface 3b of the second heat sink 3 in a wider area and filling the gaps.

In other words, the protrusion 2c is formed in the vicinity of the outline of the semiconductor device 2 where the fluctuation due to the warp is larger, and abuts to the second surface 3b of the second heat sink 3 earlier than the main surface 2a of the semiconductor device 2 in a situation where the semiconductor device 2 is warped. As a result, the protrusion 2c ensures the gap between the semiconductor device 2 and the second heat sink 3, and assists the bonding member to flow into the gap between them. Therefore, the protrusion 2c prevents the bonding member 6 from generating the voids.

The protrusion 2c is made of an arbitrary material such as resin material or metal material. In a situation where the protrusion 2c is made of the resin material, the protrusion 2c may be formed by any wet film forming method such as potting. In a situation where the protrusion 2c is made of the metal material, the protrusion 2c may be formed by any method such as electrolytic plating. In a situation where the protrusion 2c is made of the metal material, the protrusion 2c is electrically independent from, for example, a circuitry part of the semiconductor device 2 for transmitting an electrical signal such as a high frequency signal.

The protrusion 2c may be abutted to the second heat sink 3, or may be bonded to the second heat sink 3. For example, the protrusion 2c includes solder and may be bonded to the second heat sink 3. In this situation, the semiconductor device 2 may provide a structure to bond the solder. Hence, the heat sink ability of the semiconductor device 2 may be further enhanced.

The protrusions 2c are, for example, columnar. As illustrated in FIG. 26, the protrusions 2c are disposed in a region abutting the second heat sink 3 as a region of the semiconductor device 2 where the wrap is larger. A predetermined region in the vicinity of the outline of the main surface 2a of the semiconductor device 2 as a region facing the second surface 3b of the second heat sink 3 is defined as an outer edge region 2aa. The protrusions 2c are formed at the outer edge region 2aa. For example, the protrusions 2c are scattered at the outer edge region 2aa outside the first wiring 26 and are disposed to surround the first wiring 26.

However, the arrangement and the shapes of the respective protrusions 2c are not limited to the above example, as long as the protrusion 2c inhibits the contact between the main surface 2a of the semiconductor 2 and the second surface 3b of the second heat sink 3 through the warp of the semiconductor device 2 and blocks the inflow of the bonding member. For example, as illustrated in FIG. 27, the protrusion 2c may have a wall shape, or may have any other shape. The arrangement of the protrusions 2c may be appropriately modified in the outer edge region 2aa.

According to the present embodiment, in addition to the advantageous effects described in the first embodiment, the semiconductor module generates advantageous effects in ensuring the gap between the semiconductor device 2 and the second heat sink 3 even though the wrap of the semiconductor device 2 occurs in the manufacturing process, suppressing the generation of the voids at the sealing member 6 and further enhancing the reliability.

### Other Embodiments

The present disclosure has been described based on examples, but it is understood that the present disclosure is not limited to the examples or structures. The present disclosure encompasses various modifications and variations within the scope of equivalents. In addition, various combinations and configurations, as well as other combinations and configurations that include only one element, more, or less, fall within the scope and spirit of the present disclosure.

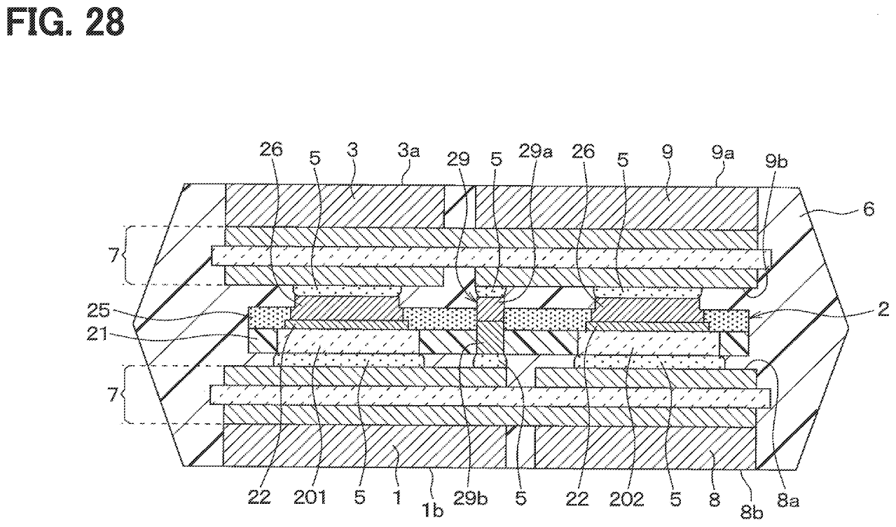

(1) For example, in the third embodiment and the modification of the third embodiment, the heat-transfer insulated substrate 7 may be disposed between the semiconductor device 2 and each of the heat sinks 1, 3, 8, 9 as illustrated in FIG. 28. In this situation, the relay member 29 is electrically connected to the electrical conductor 71 of the heat-transfer insulated substrate 7, and is electrically independent from each of the heat sinks 1, 3, 8, 9 and is thermally connected to each of the heat sinks 1, 3, 8, 9.

(2) In the third embodiment and the modification of the third embodiment, the 2 in 1 structure in which two element portions covered by one bonding member 6 is described. However, the number of element portions may be three or more. Even in this situation, the semiconductor module is thinner and has a lower thermal resistance as compared with comparative semiconductor modules.

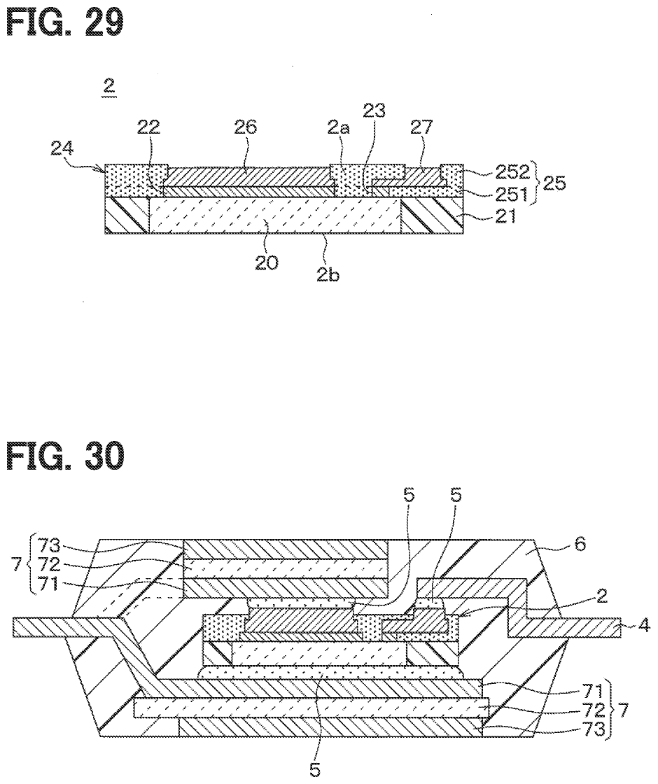

(3) In each of the embodiments described above, the first wiring 26 and the second wiring 27 in the semiconductor device 2 have a shape protruding outwards from the outer main surface of the insulating layer 25. However, as illustrated in FIG. 29, the first wiring 26 and the second wiring 27 may have a shape recessed inwards from the outer main surface of the insulating layer 25.

(4) In the second embodiment, the first heat sink member includes the first heat sink 1 and the heat-transfer insulated substrate 7, and the second heat sink member includes the second heat sink 3 and the heat-transfer insulated substrate 7. However, as illustrated in FIG. 30, each of the first heat sink member and the second heat sink member may include only the heat-transfer insulated substrate 7.

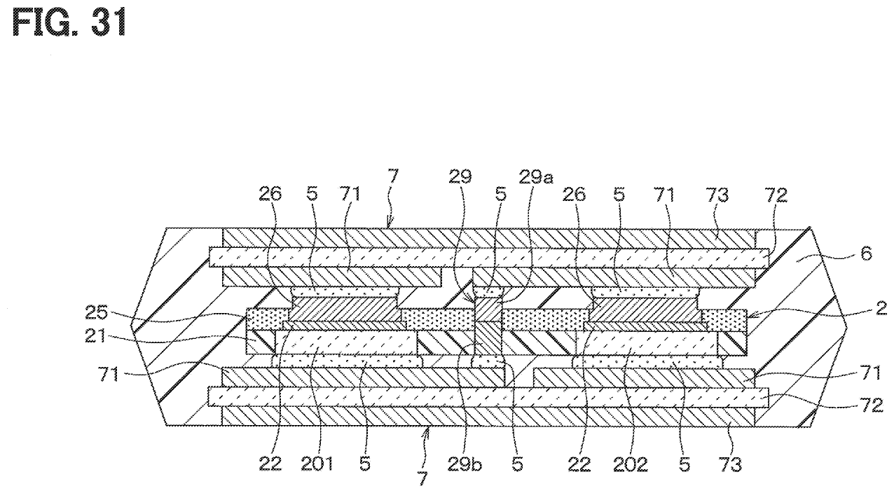

Similarly, in other modification of the third embodiment described in the above-mentioned (1), each of the first to fourth heat sink members may include only the heat-transfer insulated substrate 7 as illustrated in FIG. 31. In this situation, in the semiconductor module, only one heat-transfer insulated substrate 7 is provided for the first and third heat sink members, and only one heat-transfer insulated substrate 7 is provided for the second and fourth heat sink members. In the heat-transfer insulated substrate 7, a portion of the electrical conductor 71 connected to the semiconductor element 201 is electrically independent from a portion of the electrical conductor 71 connected to the semiconductor element 202. However, the thermal conductor 73 may not have to be patterned.

(5) In the first and second embodiments, the semiconductor element 20 in the semiconductor device 2 generates a current in the thickness direction. In other words, the semiconductor element 20 is a vertical type. However, the semiconductor element 20 is not restricted to this example. For example, the semiconductor element 20 may have a structure such that the first electrode 22, the second electrode 23 and the third electrode are formed on the identical plane.

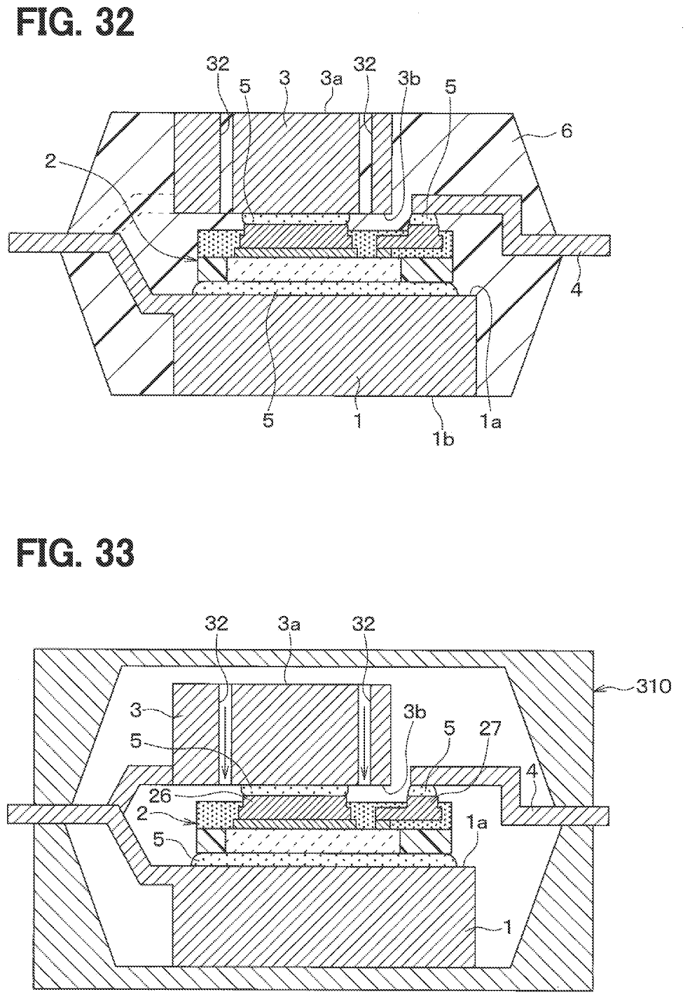

(6) In the first embodiment, for example, as illustrated in FIG. 32, the first heat sink 3 may have a through hole for connecting the first surface 3a and the second surface 3b at a position outside the region bonded to the semiconductor device 2. The through hole 32 serves as a filling route for filling the resin material (hereinafter referred to as “sealing member”) in the sealing member 6 between the semiconductor device 2 and the second heat sink 3 when the sealing member 6 is molded.

For example, as illustrated in FIG. 33, the through hole 32 becomes a path to which the sealing member flows when the sealing member is poured, after the work in which the first heat sink 1, the semiconductor device 2, the second heat sink 3 and the lead frame 4 are bonded is set at the mold 310. The work is arranged so that the first surface 3a of the second heat sink 3 is not in contact with the inner wall of the mold 310. As illustrated by an arrow in FIG. 33, the sealing member flows from the first surface 3a to the second surface 3b and fills the gap between the semiconductor device 2 and the second heat sink 3. It is possible to manufacture the semiconductor module illustrated in FIG. 32 by exposing the first surface 3a of the second heat sink 3 by, for example, grinding after hardening the sealing member. As a result, as similar to the fifth embodiment, the filing ability of the sealing member 6 is further enhanced in the semiconductor module.

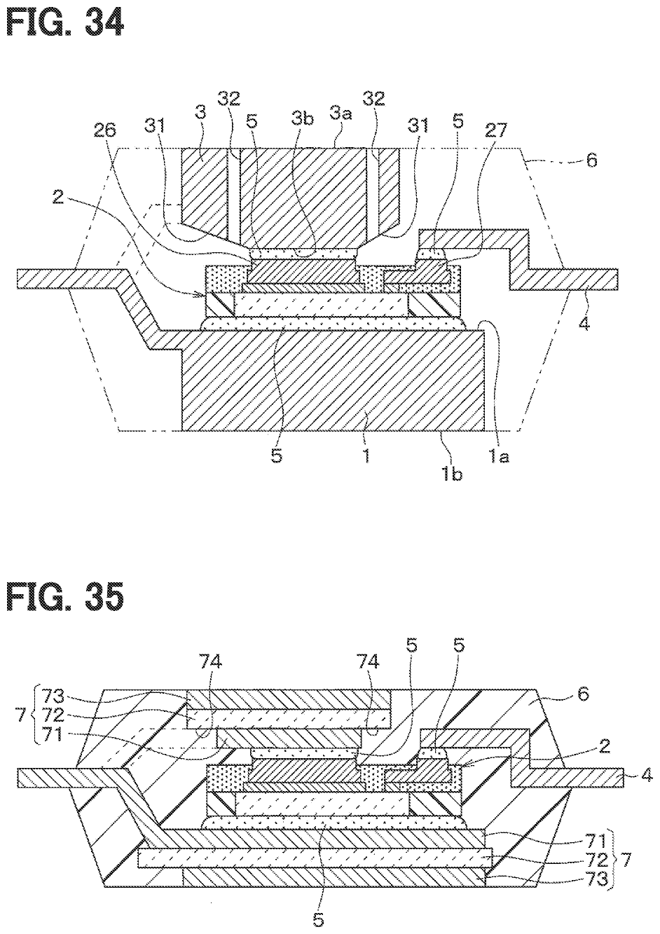

For example, as illustrated in FIG. 34, the through hole may be formed at the second heat sink 3 in the fifth embodiment and the modification of the fifth embodiment. In this situation, the through hole 32 is formed at the recessed portion 31 of the second heat sink 3, and enhances the filling ability of the sealing member 6 in the gap between the semiconductor device 2 and the second heat sink 3 along with the recessed portion 31.

The through hole 32 may be formed at the second heat sink 3 in the third embodiment and the modification of the third embodiment. In this situation, a through hole corresponding to the through hole 32 may be formed at the fourth heat sink 9, and the filling ability of the sealing member 6 is further enhanced.

(7) In a situation where a portion or an entire portion of the second heat sink member and the fourth heat sink member, for example, as illustrated in FIG. 35, the heat-transfer insulated substrate 7 may have a stepped portion 74 at the outer peripheral part of the electrical conductor 71. As a result, the sealing member 6 easily enters the gap between the heat-transfer insulated substrate 7 and the main surface 2a of the semiconductor device 2, and the filling ability of the sealing member 6 is enhanced in the semiconductor module.

What is claimed is:

1. A semiconductor module comprising:
a first heat sink member;
a semiconductor device including
a semiconductor element,
a first sealing member covering the semiconductor element,
a first wiring and a second wiring electrically connected to the semiconductor element, and
a rewiring layer disposed on the semiconductor element and the sealing member;
a second heat sink member disposed on the semiconductor device;
a lead frame electrically connected to the semiconductor device through a bonding member; and
a second sealing member covering a portion of the first heat sink member, the semiconductor and a portion of the second heat sink member,
wherein the second heat sink member has a first surface and a second surface,
wherein the second surface of the second heat sink member faces the semiconductor device,
wherein the semiconductor device has a portion protruded from an outline of the second surface of the second heat sink member, and
wherein the second wiring has an end extending to the portion of the semiconductor device protruded from the outline of the second surface of the second heat sink member, and the end of the second wiring is electrically connected to the lead frame through the bonding member.

2. The semiconductor module according to claim 1,
wherein the first heat sink member has an upper surface facing the semiconductor device, and
wherein the semiconductor device is disposed inside an outline of the upper surface.

3. The semiconductor module according to claim 1,
wherein each of the first heat sink member and the second heat sink member is a heat sink, and
wherein at least one of the first heat sink member or the second heat sink member is included in an electrical conductive path.

4. The semiconductor module according to claim 1,
wherein each of the first heat sink member and the second heat sink member is a heat-transfer insulated substrate.

5. The semiconductor module according to claim 1,
wherein each of the first heat sink member and the second heat sink member includes a heat sink and a heat-transfer insulated substrate stacked together, and
wherein the heat-transfer insulated substrate is connected to the semiconductor device through the bonding member.

6. The semiconductor module according to claim 1,
wherein the semiconductor element is a first semiconductor element,
wherein the semiconductor device further includes a relay member and a second semiconductor element that are disposed at the portion of the semiconductor device protruded from the outline of the second surface of the second heat sink member,
wherein the semiconductor module further comprises a third heat sink member and a fourth heat sink member opposed to each other,
wherein the second semiconductor element is sandwiched between the third heat sink member and the fourth heat sink member,
wherein the semiconductor device has a main surface facing the second heat sink member and a rear surface as a surface opposed to the main surface,
wherein the third heat sink member faces the rear surface of the semiconductor device, and is disposed to be separated from the first heat sink member across the second sealing member,
wherein the fourth heat sink member faces the main surface of the semiconductor device, and is disposed to be separated from the second heat sink member across the second sealing member, and
wherein the relay member includes at least one relay member extending in a direction connecting the main surface and the rear surface, and having a first end electrically connected to the first heat sink member through the bonding member and a second end electrically connected to the fourth heat sink member through the bonding member.

7. The semiconductor module according to claim 6,
wherein, as viewed in a direction normal to the main surface of the semiconductor device, a portion of the relay member exposed from the rewiring layer at the main surface of the semiconductor device is offset against a portion of the relay member exposed from the second sealing member at the rear surface of the semiconductor device.

8. The semiconductor module according to claim 7,
wherein a cross sectional shape of the relay member has at least one stepped portion in a direction connecting the main surface of the semiconductor device and the rear surface of the semiconductor device.

9. The semiconductor module according to claim 6,
wherein each of the third heat sink member and the fourth heat sink member is a heat sink.

10. The semiconductor module according to claim 6,
wherein each of the third heat sink member and the fourth heat sink member is a heat-transfer insulated substrate.

11. The semiconductor module according to claim 1,
wherein the lead frame includes:
a first end portion connected to the second wiring through the bonding member; and
a second end portion opposed to the first end portion,
wherein a direction from the first end portion to the second end portion is defined as an extending direction, and
wherein the lead frame further includes:
a boundary portion being a boundary portion between the first end portion and the second end portion, the boundary portion having a change in an orientation of the extending direction; and
a stress relaxing portion being a portion between the first end portion and the boundary portion, the stress relaxing portion having at least one of a thickness of the lead frame, a width of the lead frame, or the orientation of the extending direction different from other portions of the lead frame.

12. The semiconductor module according to claim 11,
wherein a portion of the lead frame between the first end portion and the boundary portion has a flat shape located on a plane, and
wherein the orientation of the extending direction at the stress relaxing portion is different from the orientation of the extending direction at the other portions of the lead frame.

13. The semiconductor module according to claim 1,
wherein the first surface of the second heat sink member is opposite to the second surface of the second heat sink,
wherein a region of the second surface bonded to the semiconductor device through the bonding member is a bonding region,
wherein a remaining region of the second surface different from the bonding region is a non-bonding region, and
wherein a portion of the non-bonding region located in a vicinity of the bonding region is a bonding vicinity region,
wherein the second heat sink member is a heat sink,
wherein at least one portion of the second heat sink member in the non-bonding region is a recessed portion recessed from the second surface towards the first surface, and
wherein a gap between the semiconductor device and the outline of the second surface in the non-bonding region is larger than a gap between the second surface in the bonding vicinity region and the semiconductor device.

14. The semiconductor module according to claim 13,
wherein the recessed portion has a tapered shape inclined towards the outline of the second surface from the bonding vicinity region.

15. The semiconductor module according to claim 14,
wherein a main surface of the recessed portion is an inclined surface,
wherein an acute angle as an angle between the inclined surface and a surface in the bonding region is defined as a tapered angle, and
wherein the tapered angle is 45 degrees or less.

16. The semiconductor module according to claim 13,
wherein the recessed portion includes the outline of the second surface, and is in a staircase shape towards the bonding vicinity region from the outline of the second surface.

17. The semiconductor module according to claim 1,
wherein a portion of the first wiring exposed from an insulating layer included in the rewiring layer is a roughened portion which is roughened, and
wherein each of a portion of the second wiring covered by the insulating layer and a portion of the second wiring exposed from the insulating layer is a roughened portion which is roughened.

18. The semiconductor module according to claim 1,
wherein the lead frame includes:
a first end portion connected to the second wiring through the bonding member; and
a second end portion opposed to the first end portion,
wherein a portion of the lead frame at the first end portion is a region having higher wettability to the bonding member than other regions of the lead frame, and
wherein the lead frame is connected to the semiconductor device through the region having higher wettability to the bonding member.

19. The semiconductor device according to claim 18,
wherein a portion of the second wiring exposed from an insulating layer included in the rewiring layer is defined as an exposing portion,
wherein a portion of the lead frame opposed to the exposing portion is defined as an opposing portion,
wherein the lead frame has a groove at a portion towards the second end portion from the opposing portion,
wherein the groove has an recessed portion and is opposite to the semiconductor device, and
wherein a region of the lead frame having the groove and a portion of the lead frame from the opposing portion to the groove has higher wettability to the bonding member than other regions of the lead frame.

20. The semiconductor module according to claim 1,
wherein a surface included in an outer main surface of the semiconductor device facing the second heat sink member is defined as a main surface,
wherein a region in a vicinity of an outline of the main surface and a part of a region where the main surface faces the second surface of the second heat sink member are defined as an outer edge region,
wherein the semiconductor device further includes a protrusion at the outer edge region, and
wherein the protrusion inhibits a contact between the second surface of the second heat sink member and the semiconductor device.

21. The semiconductor module according to claim 20,
wherein the protrusion has a solder, and is bonded to the second surface of the second heat sink.

22. A semiconductor device comprising:
a semiconductor element having a first surface and a second surface opposed to the first surface;
a sealing member surrounding the semiconductor element; and
a rewiring layer covering the first surface of the semiconductor element and a portion of the sealing member,
wherein the semiconductor device is included in a semiconductor module having a double-sided heat sink structure with a first heat sink member and a second heat sink member,
wherein the semiconductor device is disposed between the first heat sink member and the second heat sink member,
wherein the rewiring layer includes an insulating layer, a first wiring and a second wiring,
wherein the first wiring is disposed in the insulating layer and has an end connected to the semiconductor element,
wherein the first wiring is disposed inside an outline of the semiconductor element in a top view of the semiconductor device,
wherein the second wiring has a first end and a second end,
wherein the second wiring is disposed in the insulating layer, and the first end of the second wiring is connected to the semiconductor element, and
wherein the second end of the second wiring extends outwards from the outline of the semiconductor element in the top view of the semiconductor device.
